(19) United States
(12) Patent Application Publication
(10) Pub. No.: US 2016/0369056 A1
(43) Pub. Date: Dec. 22, 2016

(54) POLYIMIDE PRECURSOR COMPOSITION AND USE THEREOF AND POLYIMIDE MADE THEREFROM

(71) Applicant: ETERNAL MATERIALS CO., LTD., KAOHSIUNG (TW)

(72) Inventors: Chung-Jen WU, KAOHSIUNG (TW); Shun-Jen CHIANG, KAOHSIUNG (TW); Po-Yu HUANG, KAOHSIUNG (TW); Meng-Yen CHOU, KAOHSIUNG (TW); Chang-Hong HO, KAOHSIUNG (TW)

(73) Assignee: ETERNAL MATERIALS CO., LTD., KAOHSIUNG (TW)

(21) Appl. No.: 15/185,928

(22) Filed: Jun. 17, 2016

(30) Foreign Application Priority Data
Jun. 17, 2015 (TW) 104119714
Dec. 4, 2015 (TW) 104140909

(51) Int. Cl. C08G 73/12; H05K 1/03; C08K 5/3472; C08G 73/10; C09D 179/08

(52) U.S. Cl. CPC C08G 73/125; C08G 73/1032; C08G 73/106; C08G 73/1042; C09D 179/085; C08K 5/3472; H05K 1/0393; H05K 1/0346; H05K 1/0326; H05K 2201/0154

(57) ABSTRACT

The present disclosure relates to a polyimide precursor composition including an amic acid ester oligomer of formula (I):

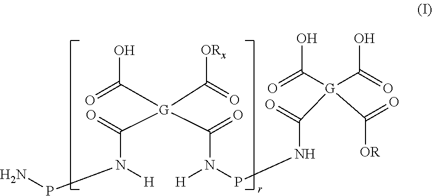

wherein r, Rₓ, G, P and R are as defined in the specification. The polyimide made from the polyimide precursor composition of the present disclosure provides adhesion upon hot pressing such that a quasi double-sided two-layer metal clad laminate with an appropriate peeling strength or a double-sided two-layer metal clad laminate with a high peeling strength can be provided.

### CROSS REFERENCE TO THE RELATED APPLICATIONS

This application claims the benefit of priority to Taiwan Patent Application Nos. 104119714 filed Jun. 17, 2015 and 104140909 filed Dec. 4, 2015, the contents of which are incorporated herein by reference in their entity.

### BACKGROUND OF THE INVENTION

1. Technical Field

The present disclosure relates to a polyimide precursor composition and the applications thereof. In particular, the present disclosure relates to a polyimide precursor composition applicable to a flexible metal clad laminate, the applications thereof and the polyimide prepared therefrom.

2. Description of the Related Art

A flexible printed circuit (FPC) board is made from the raw materials of a flexible insulation layer and copper foil which have the capacity to endure bending deformation. Due to its flexibility and bendability, FPC enables three-dimensional wiring through adaptation to the size and shape of the product and is light and thin, making it one of the essential components in various high-tech devices such as cameras, video cameras, displays, disk drives, printers, mobile phones and other such devices. The properties of raw materials affect the performance of the FPC and the capacity of raw material supply affect the yield of the FPC. The raw materials used in a FPC include resin, copper foil, adhesive, coverlay, flexible copper clad laminate (FCCL). Polyimide is superior in ductility, coefficient of thermal expansion, thermal stability and mechanical property, etc., and is thus a common resin material for FPC.

A flexible metal clad laminate, for example, flexible copper clad laminate (FCCL), is an upstream material for a flexible printed circuit board. The existing FCCLs may be divided, in light of their structures, into three-layer FCCLs (3L FCCLs) with adhesive and two-layer FCCLs (2L FCCLs) without adhesive. The 2L FCCL is made by a special process, contains no low heat-resistant adhesives such as epoxy or acrylate resins, and is thus more reliable. Moreover, 2L FCCL is better suited to development of thinner products, and thus is gradually replacing 3L FCCL in practice.

The FCCLs may be divided, in light of the circuit configuration requirements of the products (e.g., printed circuit boards), into single-sided and double-sided FCCLs. Single-sided FCCL is the most fundamental FCCL. It has a copper foil layer useful for circuit formulation clad only on one side thereof. Single-sided FCCL has the advantages of easy fabrication process, low cost, and good flexibility. Double-sided FCCL has a copper foil layer clad on both upper and lower sides. Accordingly, circuits may be formed on both sides of the double-sided FCCL, and may electrically connect to each other by a via hole. Therefore, double-sided FCCL can achieve a higher integration, is beneficial to controlling electrical resistance, and is useful for circuit fabrication simultaneously on both sides, so as to save time.

The structure of a general double-sided polyimide FCCL comprises, sequentially, copper foil, a thermoplastic polyimide layer, a polyimide layer, a thermoplastic polyimide layer and copper foil, and may be prepared from bottom to top by coating one layer on another layer. In other words, the existing polyimide FCCL structure can be prepared sequentially by coating a thermoplastic polyimide layer on a copper foil, coating a polyimide layer on the thermoplastic polyimide layer, coating another thermoplastic polyimide layer on the polyimide layer and then laminating it onto another copper foil. Another process is to coat a thermoplastic polyimide layer on the opposing sides of a polyimide layer, form a structure in the order of a thermoplastic polyimide layer, a polyimide layer and a thermoplastic polyimide layer via baking, and then laminate a layer of copper foil onto the opposing sides of the above structure using a hot press machine.

The existing process involves several repetitions of coating and lamination, is complicated and takes a lot of time. Moreover, two thermoplastic polyimide layers are needed in the existing process. A thermoplastic polyimide layer is inferior to a polyimide layer in dimensional stability and does not have good heat resistance, and so it is easy for foam and delamination to occur in the FCCL during a high temperature process, thereby affecting the yield.

A new process has been introduced to the industry. In this process, a double-sided polyimide FCCL is prepared by laminating two single-sided FCCLs, each of which comprises copper foil, a polyimide layer on the copper foil and a thermoplastic polyimide layer on the polyimide layer, in the manner that the thermoplastic polyimide layers on the two single-sided FCCLs face each other. With the new process, there is no need to repeat the coating and lamination steps layer-by-layer as the existing process does. In other words, in the new process, a double-sided polyimide FCCL can be prepared by carrying out the procedure for preparing single-sided FCCLs once to provide the single-sided FCCLs which are coated with a polyimide layer and then laminating two of such single-sided FCCLs to each other. However, since the adhesion between two polyimide layers is worse, a thermoplastic polyimide layer (TPI) is still required. Thermoplastic polyimide has a lower glass transition temperature (Tg), inferior heat resistance, higher thermal expansion coefficient, greater size change during expansion and contraction, and is prone to cause warpage or delamination of the FCCL.

In addition, single-sided FCCLs are generally used to prepare single-sided flexible printed circuits. However, single-sided FCCLs tend to warp. Therefore, during printing of the single-sided circuit, a photoresist is applied not only to the surface of the copper foil for circuit fabrication, but also to the surface of the polyimide layer, such that structural balance is achieved on two opposite sides of the FCCL, thereby alleviating the occurrence of warpage. The photoresist is removed in a subsequent step. However, this increases the fabrication cost.

Through continuous research, the inventors have found a novel polyimide precursor composition. The polyimide produced therefrom has adhesive properties upon hot pressing. In the present disclosure, a quasi double-sided two layer metal clad laminate may be prepared by adjusting the lamination temperature and pressure, and easily separated into two single-sided flexible circuit boards after the fabrication of flexible printed circuit thereon. This eliminates the disadvantage currently existing in the process of preparing single-sided flexible printed circuit from a single-sided FCCL and results in the advantages of a simplified process and reduced cost. Also, in the present disclosure, the lamination temperature and pressure may be adjusted to prepare a double-sided two layer metal is clad laminate having high peeling strength, thereby reducing the complexity in the processes existing in the industry for preparing double-sided FCCLs.

### SUMMARY

An aspect of the present disclosure is to provide a novel polyimide precursor composition. The polyimide produced therefrom provides adhesion upon hot pressing.

The polyimide precursor composition of the present disclosure comprises an amic acid ester oligomer of formula (I):

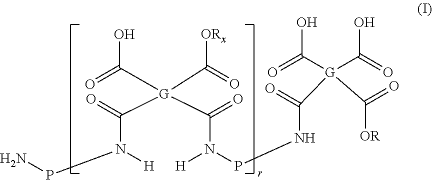

wherein:

r is an integer ranging from 1 to 200;

Each Rₓ is independently H, C₁-C₁₄alkyl or a moiety bearing an ethylenically unsaturated group;

Each R is independently C₁-C₁₄alkyl, C₆-C₁₄aryl or aralkyl, or a moiety bearing an ethylenically unsaturated group;

Each G is independently a tetravalent organic group; and

Each P is independently a divalent organic group, wherein based on the total moles of the divalent organic groups P in the composition, about 0.1 mol % to about 10 mol % of the divalent organic groups is selected from the group consisting of (i) a divalent siloxane organic group having formula (A), (ii) C₂-C₁₄alkylene, and a combination thereof:

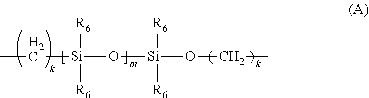

wherein each R₆ is independently H, a linear or branched alkyl having 1 to 14 carbon atoms, or phenyl, k may be the same or different and is an integer greater than 0, and m is an integer greater than 0.

Another aspect of the present disclosure is to provide a use of the polyimide precursor composition for a polyimide layer in a metal clad laminate.

The polyimide precursor composition of the present disclosure is applicable to a flexible metal clad laminate, such as FCCL. The resulting flexible metal clad laminate is light and thin, has good flexibility and electrical characteristics, and also requires less time and expense on subsequent processing. Furthermore, the polyimide precursor composition of the present disclosure can be applied widely, and when needed, it can be used to prepare a quasi double-sided two layer metal clad laminate or a double-sided two layer metal clad laminate by controlling process parameters.

To make the objectives, technical features and advantages of the present disclosure clear and comprehensible, detailed description is given below by way of some specific embodiments.

### BRIEF DESCRIPTION OF THE DRAWINGS

The invention will be described according to the appended drawings, in which:

FIG. 1 is a schematic view of a metal clad laminate having a polyimide according to the present disclosure;

FIG. 2 is a schematic view showing the preparation of two single-side wired flexible circuit boards by using a metal clad laminate having a polyimide according to the present disclosure; and

FIG. 3 is a schematic view showing the separation of two single-side wired flexible circuit boards according to the present disclosure.

### DETAILED DESCRIPTION

For ease of understanding the present disclosure, several terms are defined hereinafter.

The term “about” means an acceptable deviation of a particular value determined by those of ordinary skill in the art, the range of which depends on how the value is measured or determined.

In the present disclosure, the term “alkyl” refers to a saturated, straight or branched hydrocarbon group, which comprises preferably 1-14 carbon atoms, and more preferably 1-6 or 1-4 carbon atoms. Examples of alkyl include, but are not limited to, methyl, ethyl, propyl (such as n-propyl and isopropyl), butyl (such as n-butyl, sec-butyl, isobutyl and tert-butyl), pentyl, hexyl, or similar groups.

In the present disclosure, the term “alkenyl” refers to an unsaturated, straight or branched hydrocarbon group containing at least one carbon-carbon double bond, which comprises preferably 2-10 carbon atoms, and more preferably 3-8 carbon atoms. Examples include, but are not limited to, ethenyl, propenyl, methyl propenyl, isopropenyl, pentenyl, hexenyl, heptenyl, 1-propenyl, 2-butenyl, 2-methyl-2-butenyl and similar groups.

In the present disclosure, the term “aryl” or “aromatic” refers to a monocyclic, bicyclic or tricyclic aromatic ring system having 6 to 14 ring carbon atoms. Examples of aryl include, but are not limited to, phenyl, tolyl, naphthyl, fluorenyl, anthryl, phenanthrenyl and similar groups.

In the present disclosure, the term “halogenated alkyl” refers to an to alkyl substituted with a halogen, wherein the “halogen” denotes fluorine, chlorine, bromine or iodine.

In the present disclosure, the term “alkoxy” refers to an alkyl attached to an oxygen atom, which comprises preferably 1-8 carbon atoms, and more preferably 1-4 carbon atoms.

In the present disclosure, the term “adhesion upon hot pressing” refers to the adhesion between one polyimide resin layer and another polyimide resin layer that is generated by applying proper heat and pressure.

The polyimide precursor composition of the present disclosure comprises an amic acid ester oligomer of formula (I):

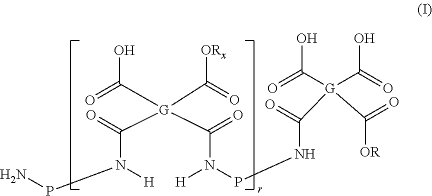

wherein:

r is an integer ranging from 1 to 200, preferably from 5 to 150, and more preferably from 9 to 100;

Each Rₓ is independently H, C₁-C₁₄alkyl or a moiety bearing an ethylenically unsaturated group;

Each R is independently C₁-C₁₄alkyl, C₆-C₁₄aryl or aralkyl, or a moiety bearing an ethylenically unsaturated group;

Each G is independently a tetravalent organic group; and

Each P is independently a divalent organic group, wherein based on the total moles of the divalent organic groups P in the composition, about 0.1 mol % to about 10 mol % of the divalent organic groups is selected from the group consisting of (i) a divalent siloxane organic group having formula (A), (ii) C₂-C₁₄alkylene, and a combination thereof:

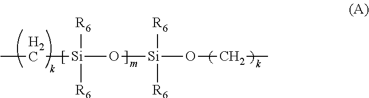

wherein each R₆ is independently H, C₁-C₁₄alkyl (preferably C₁-C₈alkyl, and more preferably C₁-C₄alkyl), or phenyl; k may be the same or different and is an integer greater than 0, for example, 1, 2, 3, 4 or 5, preferably an integer between 2 to 5; and m is an integer greater than 0, for example, 1, 2, 3, 4 or 5, preferably an integer between 1 to 5. According to one embodiment of the present disclosure, the divalent organic group is not crosslinkable. Non-crosslinkable divalent organic group allows for better flexural endurance of the resulting polymer layer. In addition to (i) a divalent siloxane organic group having formula (A), (ii) C₂-C₁₄alkylene, or a combination thereof, each of the divalent organic groups P independently comprises a divalent aromatic group or a divalent heterocyclic group.

In one embodiment of the present disclosure, based on the total moles of the divalent organic groups P in the composition, the amount of (i) a divalent siloxane organic group having formula (A), (ii) C₂-C₁₄alkylene, or a combination thereof may be 0.1, 0.5, 1, 2, 2.5, 3, 3.5, 4, 4.5, 4.9, 5, 6, 7, 8, 9 or 10 mol %, and is preferably from about 0.5 mol % to about 7.5 mol %, more preferably from about 1 mol % to 5 mol %.

A slight amount of siloxane group is usually introduced to the polymeric structure of polyimide to increase the adhesion of polyimide to glass or wafer. However, the inventors of the present application have found that introducing (i) a group having formula (A), (ii) C₂-C₁₄alkylene, or a combination thereof in a proper amount into the polymeric structure of polyimide can make the resulting polyimide layer have adhesion with another polyimide layer when the two are laminated by applying pressure under a high temperature condition. As stated above, based on the total moles of the divalent organic groups P in the composition, the amount of (i) a group having formula (A), (ii) C₂-C₁₄alkylene, or a combination thereof may be from about 0.1 mol % to about 10 mol %. When the amount of (i) a group having formula (A), (ii) C₂-C₁₄alkylene, or a combination thereof is too high (for example, higher than 10 mol %), then the glass transition temperature of the resulting polyimide layer would be too low, the mechanical strength (for example, tensile strength), the flexural endurance, the dimensional stability, and the flame retardance would be poor, and the coefficient of thermal expansion of the polyimide layer would be too large, such that the prepared laminate is prone to warpage. The amount may be further controlled such that it is not higher than 7.5 mol % or is less than 5 mol %; when the amount of the groups having formula (A), (ii) C₂-C₁₄alkylene, or a combination thereof is too low, there is no adhesion between the polyimide layers. If necessary, the amount can be controlled such that it is at least 0.5 mol % or 1 mol %. In one embodiment of the present disclosure, based on the total moles of the divalent organic groups P in the composition, the amount of (i) the group having formula (A), (ii) C₂-C₁₄alkylene, or a combination thereof may be from about 2 mol % to about 4.9 mol %.

According to one embodiment of the present disclosure, (i) the group having formula (A) is selected from the group consisting of:

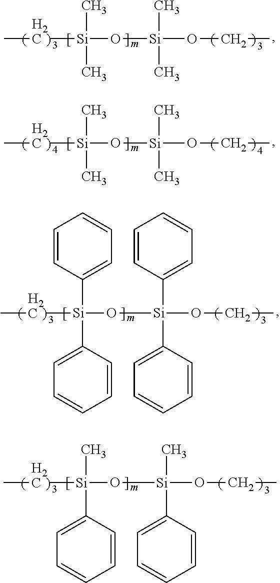

and a combination thereof, wherein m is an integer between 1 to 5; and is more preferably

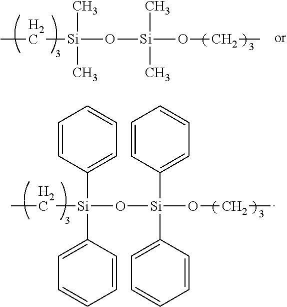

According to one embodiment of the present disclosure, (ii) C₂-C₁₄alkylene is a straight or branched alkylene, which has preferably 3-12 carbon atoms and is more preferably selected from the group consisting of:

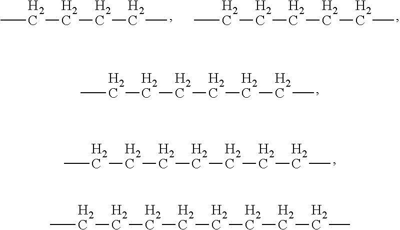

and a combination thereof.

According to one embodiment of the present disclosure, the ethylenically unsaturated group may be ethenyl, propenyl, methylpropenyl, n-butenyl, isobutenyl, ethenylphenyl, propenylphenyl, propenyloxymethyl, propenyloxyethyl, propenyloxypropyl, propenyloxybutyl, propenyloxypentyl, propenyloxyhexyl, methylpropenyloxymethyl, methylpropenyloxyethyl, methylpropenyloxypropyl, methylpropenyloxybutyl, methylpropenyloxypentyl, methylpropenyloxyhexyl or a group of the following formula (B):

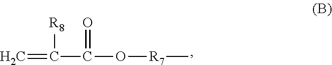

wherein R₇ is phenylene, C₁-C₈alkylene, C₂-C₈alkenylene, C₃-C₈cycloalkylene or C₁-C₈hydroxylalkylene; and R₈ is hydrogen or C₁-C₄alkyl.

According to one embodiment of the present disclosure, each R is independently selected from the group consisting of:

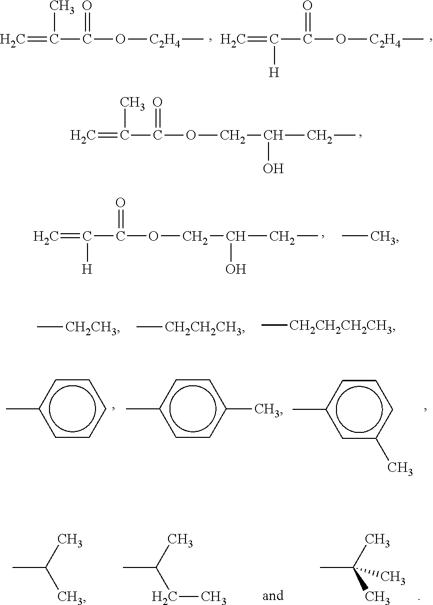

According to one preferred embodiment of the present disclosure, each Rₓ is independently H, methyl, ethyl, propyl, 2-hydroxypropyl methacrylate, ethyl methacrylate, ethyl acrylate, propenyl, methylpropenyl, n-butenyl or isobutenyl, more preferably H or methyl.

According to one embodiment of the present disclosure, each Rₓ is independently H, methyl, ethyl, propyl, 2-hydroxypropyl methacrylate, ethyl methacrylate, ethyl acrylate, propenyl, methylpropenyl, n-butenyl or isobutenyl, more preferably H or methyl.

According to one embodiment of the present disclosure, in addition to (i) the divalent siloxane organic group having formula (A), (ii) C₂-C₁₄alkylene, or a combination thereof, the divalent organic groups P independently comprises a divalent aromatic group or a divalent heterocyclic group and are preferably selected from, for example, the following groups:

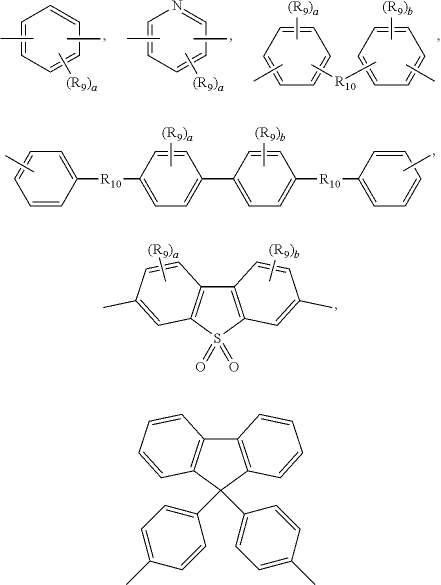

and a combination thereof, wherein each R₉ is independently H, C₁-C₄alkyl, C₁-C₄perfluoroalkyl, C₁-C₄alkoxyl or halogen; each a is independently an integer from 0 to 4; each b is independently an integer from 0 to 4; R₁₀ is a covalent bond, or selected from the following groups: —O—, —S—, —CH₂—, —S(O)₂—,

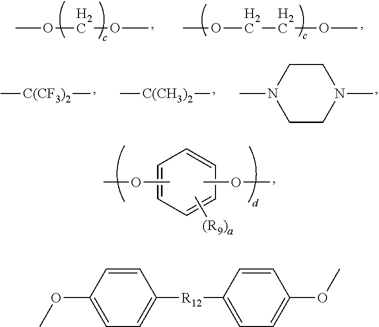

and a combination thereof, wherein c and d are each independently an integer from 1 to 20, R₁₂ is —S(O)₂—, a covalent bond, C₁-C₄alkylene or C₁-C₄ perfluoroalkylene.

Each of the above-mentioned divalent aromatic group and divalent heterocyclic group is preferably selected from, for example, the following groups:

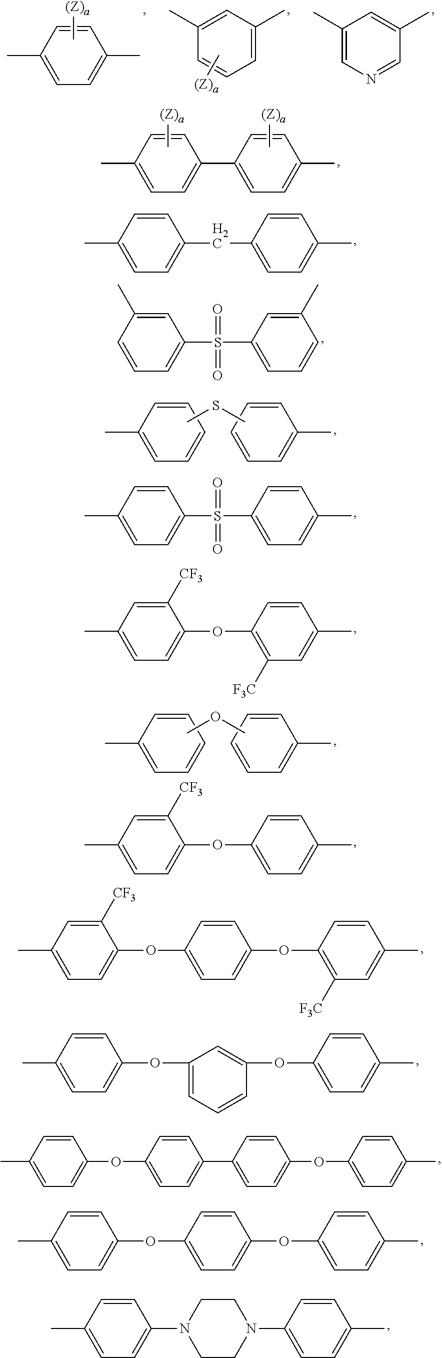

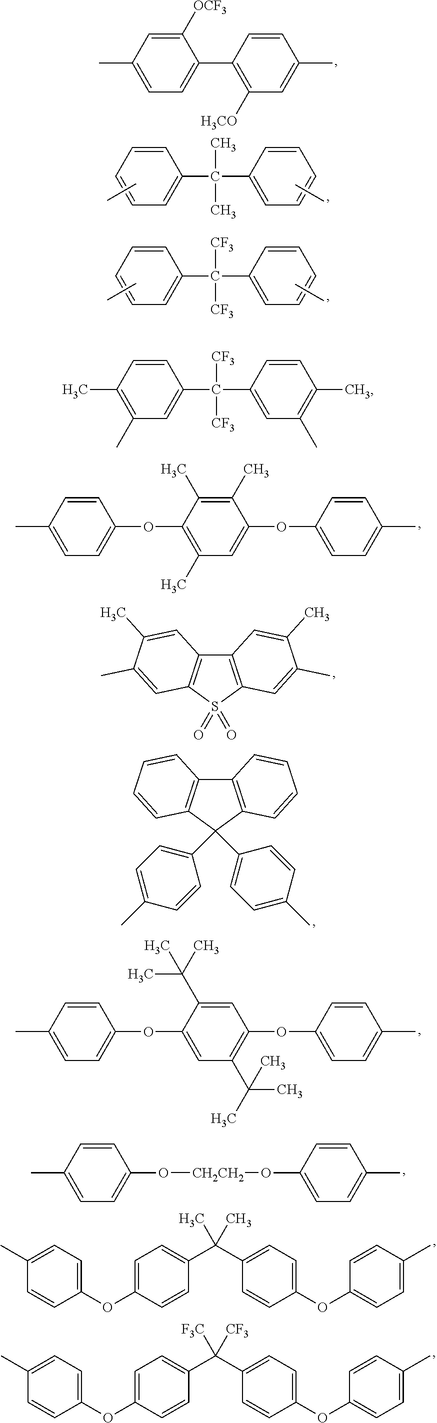

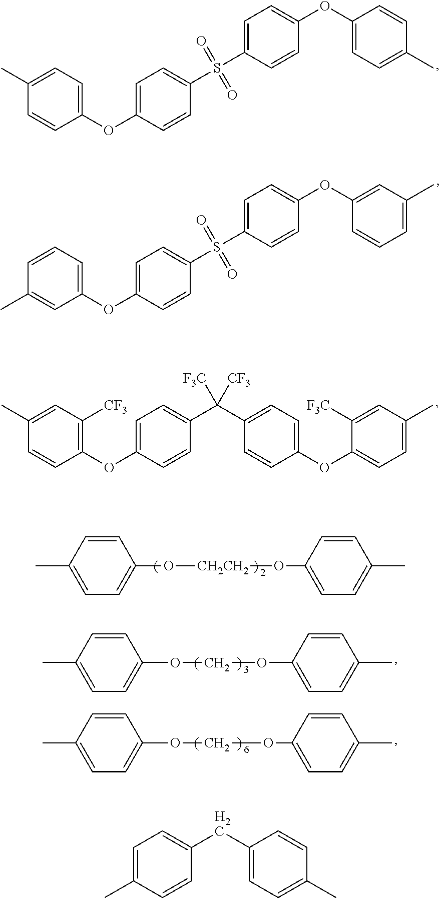

and a combination thereof.
wherein each a is independently an integer from 0 to 4, and each z is independently H, methyl, trifluoromethyl or halogen.

To allow the polyimide layer to have superior thermal stability, mechanical properties, electrical properties, and chemical resistance after curing, each of the above-mentioned divalent aromatic group and divalent heterocyclic group is more preferably selected from, for example, the following groups:

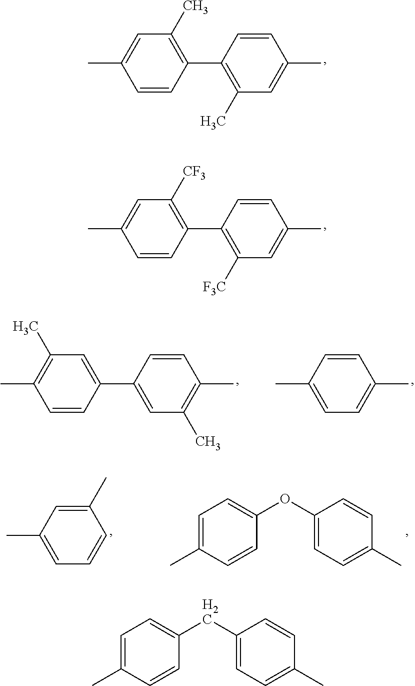

and a combination thereof.

According to one embodiment of the present invention, G is tetravalent aromatic group and is preferably and independently selected from the following groups:

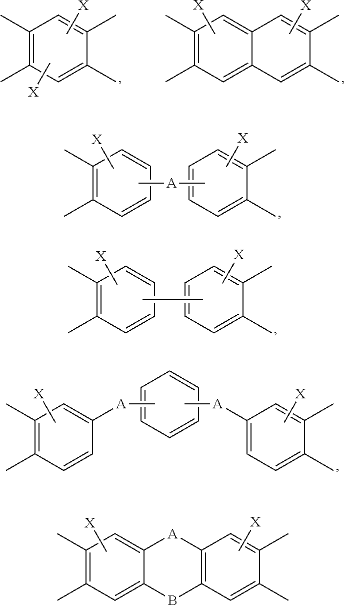

and a combination thereof.
wherein each X is independently H, halogen, C₁-C₄perfluoroalkyl, C₁-C₄alkyl; and A and B are independently, at each occurrence, a covalent bond, C₁-C₄alkylene unsubstituted or substituted with one or more radicals selected from C₁-C₄alkyl, C₁-C₄perfluoroalkylene, C₁-C₄alkoxylene, silylene, —O—, —S—, —C(O)—, —OC(O)—, —S(O)₂—, —C(=O)O—(C₁-C₄alkylene)-(OC(═O)—, phenylene, biphenylene or

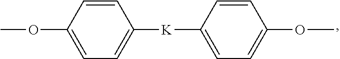

wherein K is —O—, —S(O)₂—, C₁-C₄alkylene or C₁-C₄ perfluoroalkylene.

G is more preferably selected from the group consisting of:

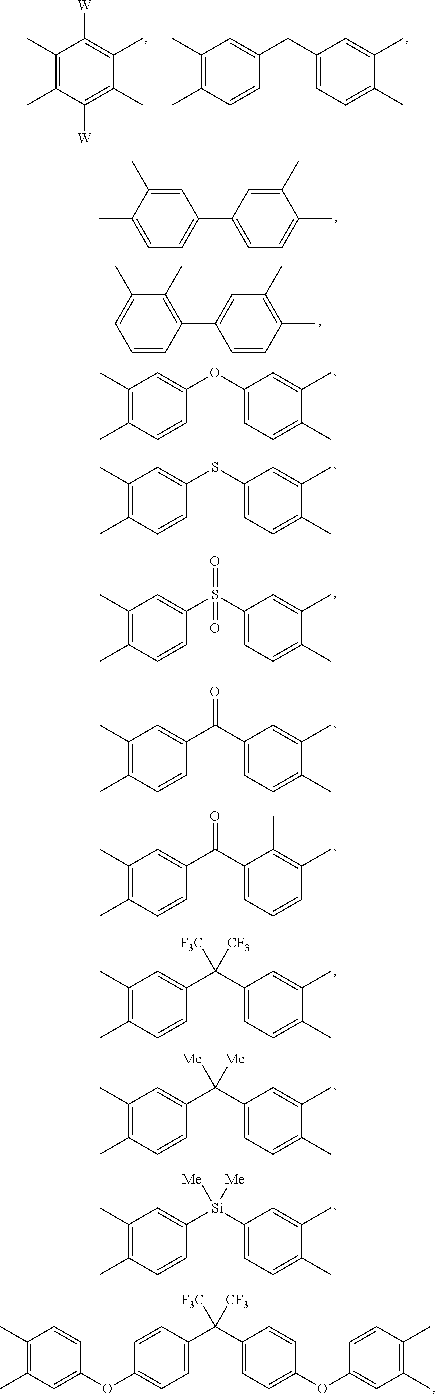

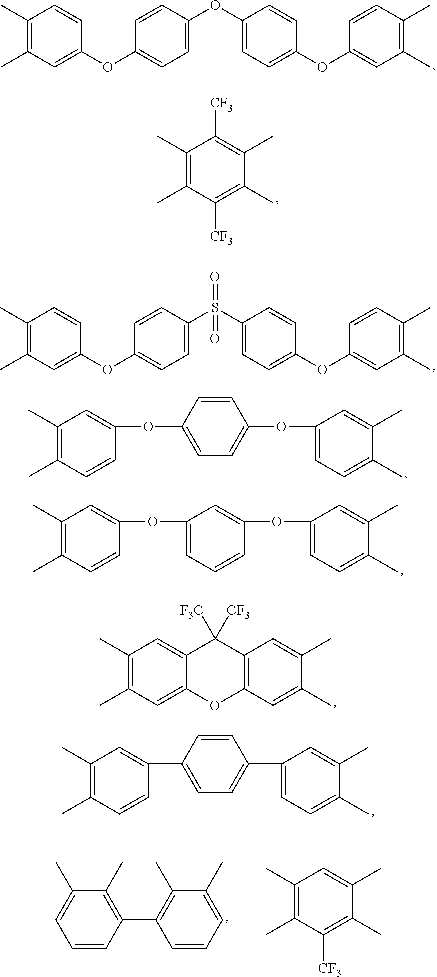

and a combination thereof.
wherein each W is independently H, methyl, trifluoromethyl or halogen.

To allow the polyimide layer to have superior thermal stability, mechanical properties, electrical properties, and chemical resistance after curing, G is most preferably a tetravalent aromatic group selected from the group consisting of:

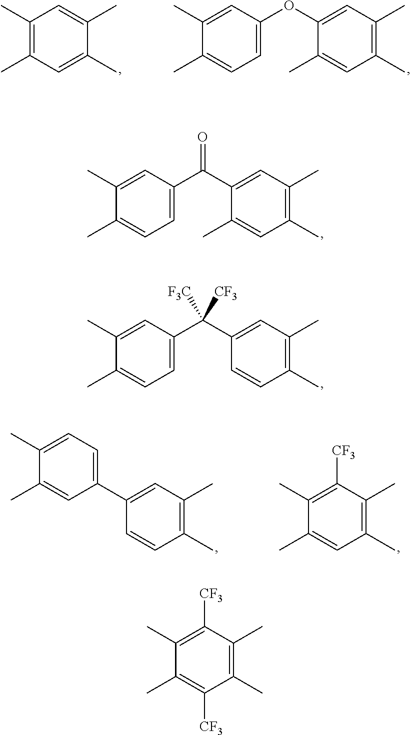

and a combination thereof.

The amic acid ester oligomer of formula (I) of the present disclosure may be prepared by the following method, without limitation thereto:
(a) reacting a dianhydride of formula (7) in an excess amount with a compound having hydroxyl (R—OH) to form a compound of formula (8);

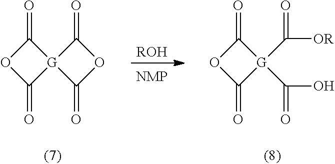

(b) after carrying out the reaction of step (a), adding an aromatic diamine monomer and a diaminosiloxane monomer or an alkylene diamine monomer (e.g., a diamine compound of formula H₂N—P—NH₂) to react with the compounds of formulae (7) and (8) and form a compound of formula (11); and

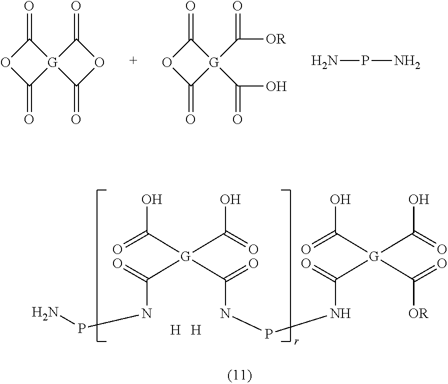

(c) optionally adding one or more compounds having a group Rₓ for carrying out reaction to form the amic acid ester oligomer of formula (I)

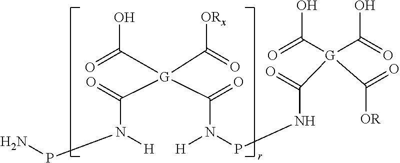

wherein R, P, Rₓ, G and r are as defined hereinbefore.

According to one embodiment of the present disclosure, the polyimide precursor composition may optionally comprises an adhesion promoter, which can form a complex with metal foil (e.g., copper foil), thereby enhancing the adhesion between metal foil and polyimide. Such adhesion promoter is also called metal adhesion promoter, for example, copper adhesion promoter. The adhesion promoters can be N-containing heterocycles, for example, 5 to 6-membered heterocycles containing 1 to 3 nitrogen atoms, such as imidazoles, pyridines or triazoles; or fused ring compounds containing any of the above-mentioned N-containing heterocycle in structure. The above N-containing heterocycles can be unsubstituted or substituted by one to three substituent group. The substituent group can be, for example, but is not limited to hydroxyl or 5 to 6-membered heterocyclyl containing 1 to 3 nitrogen atoms. According to the present disclosure, the adhesion promoter, if present, is in an amount of about 0.1 parts by weight to about 2 parts by weight based on 100 parts by weight of the amic acid ester oligomer, and is preferably in an amount of about 0.2 parts by weight to about 1.5 parts by weight based on 100 parts by weight of the amic acid ester oligomer.

Examples of the adhesion promoter include, but are not limited: 1,2,3 -triazole, 1,2,4-triazole, 3-amino-1,2,4-triazole, 3,5-diamino-1,2,4-triazole, imidazole, benzimidazole, 1,2,3,4-tetrahydrocarbazole, 2-hydroxybenzimidazole, 2-(2-hydroxyphenyl)-1H-benzimidazole, 2-(2-pyridyl)-benzimidazole, 2-(3-pyridyl)-1H-benzimidazole or a combination thereof.

In order to lower the cyclization temperature for producing polyimide such that the amic acid ester oligomer (i.e., the polyimide precursor) can be imidized at a lower temperature (for example, not higher than 300° C. or not higher than 250° C.) to form polyimide, the polyimide precursor composition of the present disclosure may optionally comprise a cyclization promoter. The cyclization promoter can generate a base upon heating to provide a base environment so as to facilitate the polymerization, cyclization and imidization of the amic acid ester oligomer of formula (I) into polyimide. Therefore, adding a cyclization promoter into a polyimide precursor composition is beneficial to lower the cyclization temperature.

The cyclization promoter of the present disclosure has the following formula:

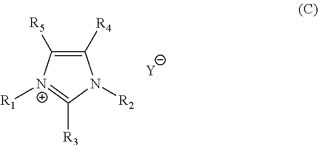

wherein R₁ and R₂ are the same or different and are each independently H, C₁-C₆alkyl, C₁-C₆haloalkyl, or C₁-C₆alkyl substituted with one or more C₆-C₁₄aryl,

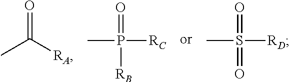

R_{A} is C₁-C₆alkyl, C₁-C₆haloalkyl, C₁-C₈alkoxy unsubstituted or substituted with one or more C₆-C₁₄aryl, or —NR_{E}R_{F}; R_{B}, R_{C}, R_{D}, R_{E} and R_{F} are the same or different, and are each independently H, C₁-C₁₄alkyl unsubstituted or substituted with one or more C₆-C₁₄aryl, or C₆-C₁₄ aryl; R₃, R₄ and R₅ are the same or different, and are each independently H, C₁-C₆alkyl unsubstituted or substituted with one or more C₆-C₁₄aryl, C₁-C₆ hydroxyalkyl, C₁-C₆cyanoalkyl, or C₆-C₁₄aryl; Y⊖ is an anionic group.

According to an embodiment of the present disclosure, the groups R₁ and R₂ in formula (C) are the same or different and are each independently C₁-C₆alkyl,

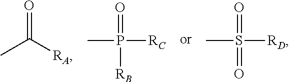

wherein R_{A} is C₁-C₆alkyl, C₁-C₆haloalkyl, C₁-C₈alkoxy unsubstituted or substituted with one or more C₆-C₁₄aryl, or —NR_{E}R_{F}; and R_{B}, R_{C}, R_{D}, R_{E} and R_{F} are the same or different and are each independent H, C₁-C₁₄alkyl, or C₆-C₁₄aryl. Preferably, R_{A} is methyl, ethyl, n-propyl, isopropyl, n-butyl, isobutyl, tert-butyl, pentyl, hexyl, trifluoromethyl, pentafluoethyl, methoxy, ethoxy, propoxy, butoxy, pentyloxy, hexyloxy, benzyloxy and fluorenylmethoxy; and R_{B}, R_{C}, R_{D}, R_{E} and R_{F} are each independently H, methyl, ethyl, n-propyl, isopropyl, n-butyl, isobutyl, tert-butyl, pentyl, hexyl, heptyl, octyl, phenyl, benzyl or diphenyl methyl.

According to one embodiment of the present disclosure, the groups R₁ and R₂ in formula (C) are the same or different and are each independently methyl, ethyl, propyl, butyl or selected from a group consisting of:

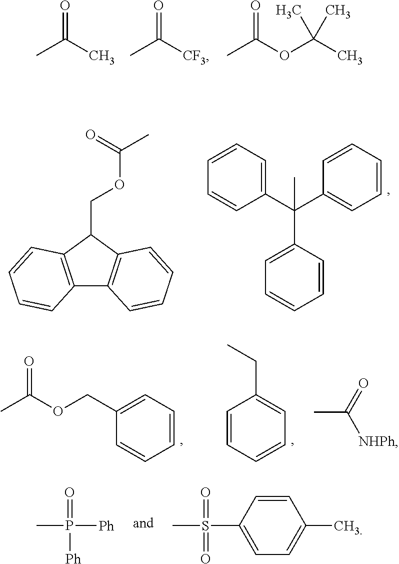

Preferably, R₁ and R₂ are the same or different and are each independently methyl, ethyl or selected from a group consisting of:

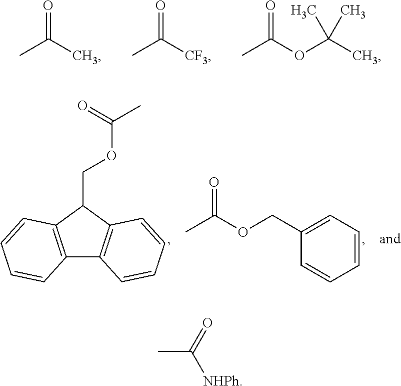

According to one embodiment of the present disclosure, R₃, R₄ and R₅ in formula (C) are the same or different and are each independently H, methyl, ethyl, n-propyl, isopropyl, n-butyl, isobutyl, tert-butyl, pentyl, hexyl, hydroxymethyl, hydroxyethyl, hydroxypropyl, hydroxybutyl, hydroxypentyl, hydroxyhexyl, cyanomethyl, cyanoethyl, cyanopropyl, cyanobutyl, cyanopentyl, cyanohexyl, phenyl, benzyl or diphenylmethyl.

Hydroxybutyl is preferably

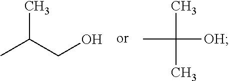

hydroxypentyl is preferably

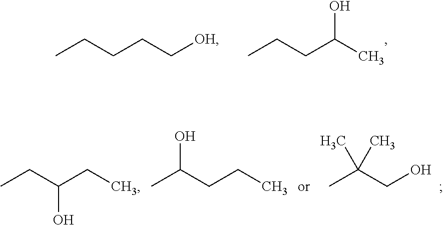

cyanobutyl is preferably

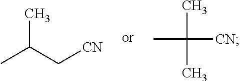

cyanopentyl is preferably

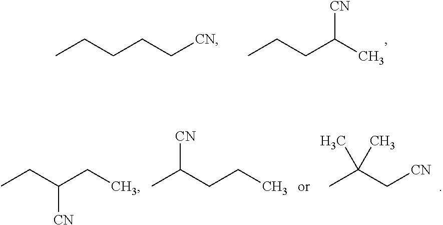

Preferably, R₃, R₄ and R₅ are the same or different and are each independently H, methyl, ethyl, n-propyl or isopropyl.

The anionic group in formula (C) is not particularly limited, examples thereof including, but not limited to, halide ion, sulfate, nitrate, phosphate, sulfonate, carbonate, tetrafluoborate, borate, chlorate, iodate, hexafluorophosphate, perchlorate, trifluoromethanesulfonate, trifluoroacetate, acetate, tert-butylcarbonate, (CF₃SO₂)₂N⁻ or tert-butyloxy. According to one embodiment of the present disclosure, the anionic group in formula (C) is halide ion or tetrafluoborate. Preferably, the halide ion is fluoride ion and chloride ion.

According to one embodiment of the present disclosure, the cyclization promoter, if present, is in an amount of about 0.1 parts by weight to about 2 parts by weight, preferably about 0.2 parts by weight to about 1.5 parts by weight, based on 100 parts by weight of the amic acid ester oligomer.

According to one embodiment of the present disclosure, the polyimide precursor composition of the present disclosure may comprise a solvent. For example, the solvent may be selected from the group consisting of (without limitation thereto): dimethyl sulfoxide (DMSO), diethyl sulfoxide, N,N-dimethyl-methanamide (DMF), N,N-diethyl-methanamide, N,N-dimethylacetamide (DMAc), N,N-diethylacetamide, N-methyl-2-pyrrolidone (NMP), N-ethyl-2-pyrrolidone (NEP), phenol, o-cresol, m-cresol, p-cresol, xylenol, halogenated phenol, pyrocatechol, tetrahydrofuran (THF), dioxane, dioxolane, propylene glycol monomethyl ether (PGME), tetraethylene glycol dimethyl ether (TGDE), methanol, ethanol, butanol, 2-butoxyethanol, γ-butyrolactone (GBL), xylene, toluene, hexamethylphosphoramide, propylene glycol monomethyl ether acetate (PGMEA) and a mixture thereof. The solvent is preferably a polar aprotic solvent, for example, a solvent selected from the following groups: dimethyl sulfoxide (DMSO), diethyl sulfoxide, N,N-dimethyl-methanamide (DMF), N,N-diethyl-methanamide, N,N-dimethylacetamide (DMAc), N,N-diethylacetamide, N-methyl-2-pyrrolidone (NMP), N-ethyl-2-pyrrolidone (NEP), γ-butyrolactone (GBL).

According to one embodiment of the present disclosure, the amount of the amic acid ester oligomer is about 10 wt % to about 70 wt %, and preferably about 15 wt % to about 50 wt %, based on the total weight of the polyimide precursor composition. The amount of the solvent is not particularly limited and can be used to make it easy to apply the composition.

The method for preparing the polyimide precursor composition of the present disclosure is not particularly limited. For example, the polyimide precursor composition of the present disclosure can be prepared by adding a suitable solvent and optional additives (for example, an adhesion promoter, a cyclization promotor, or other suitable additives (such as a leveling agent, a defoaming agent, a coupling agent, a dehydrating agent, a catalyst, etc.)) in an appropriate proportion, after the preparation of the polyimide precursor of formula (I), and agitating the mixture in a nitrogen system.

The present disclosure further provides a polyimide produced from the above polyimide precursor composition.

The polyimide of the present disclosure can be a reaction product obtained by, for example, heating the above polyimide precursor composition under suitable conditions. The polyimide of the present disclosure has excellent physical properties, mechanical properties, low thermal expansion coefficient, and good adhesion to metal and is useful as a polyimide layer in a metal clad laminate. In one embodiment of the present disclosure, the above polyimide precursor composition is applied to a substrate, such as copper foil substrate, and then heated and cyclized to form a polyimide layer on a substrate.

In conventional processes for synthesizing polyimides, it was necessary to first synthesize a poly(amic acid) having a higher molecular weight as a precursor. However, since the higher molecular weight results in an overly high viscosity, the operability of the precursor becomes worse and the leveling properties during coating become poor. Moreover, the overly high molecular weight of poly(amic acid) causes extreme internal stress due to the interaction between the molecules and the shortening of molecular chains during the imidization of the precursor. The extreme internal stress causes warp and deformation of the coated substrate.

The amic acid ester oligomer of the present disclosure contains both ester (—C(O)OR) and carboxyl (—C(O)OH) terminal groups which are in a meta-stable status and do not react with the amino (—NH₂) groups of the amic acid ester oligomer at room temperature. In addition, since the amic acid ester oligomer has a lower molecular weight, the precursor composition has excellent operability and the leveling effect can be achieved during coating. During post curing, when the temperature is increased to 100° C. above, the ester (—C(O)OR) and carboxyl (—C(O)OH) terminal groups can be reduced into anhydrides with the amino groups, and then form larger polymers via further polymerization and condensation reaction, so as to provide polyimides exhibiting excellent thermal, mechanical, and stretching properties. In comparison with conventional techniques, the present disclosure uses amic acid ester oligomers with lower viscosities, rather than a polyamic polymer having a higher viscosity, as the precursors. Therefore, the precursors exhibit better leveling and operative properties during coating.

When conducting imidization reaction using the precursor composition of the present disclosure, the amic acid ester oligomer is first subjected to intramolecular cyclization and then intermolecular polymerization and cyclization, which can effectively reduce the remaining internal stress in the resulting polyimide. In comparison with conventional techniques, the cyclized polyimide obtained from the precursor composition of the present disclosure has the advantage of avoiding warpage.

Since the precursor composition for the polyimides of the present invention has a molecular weight lower than that of the conventional poly(amic acid), it has a lower viscosity and excellent operability and can formulated with a high solids content. Therefore, the coating layer contains less solvent so that the baking time can be shortened, the baking temperature can be lowered and the volume shrinkage caused by solvent evaporation can be reduced. Also, the drying and film forming speed is faster and the number of coating times for attaining the desired thickness of the product can be reduced.

The present disclosure further provides a use of the above polyimide precursor composition in a polyimide layer of a metal clad laminate.

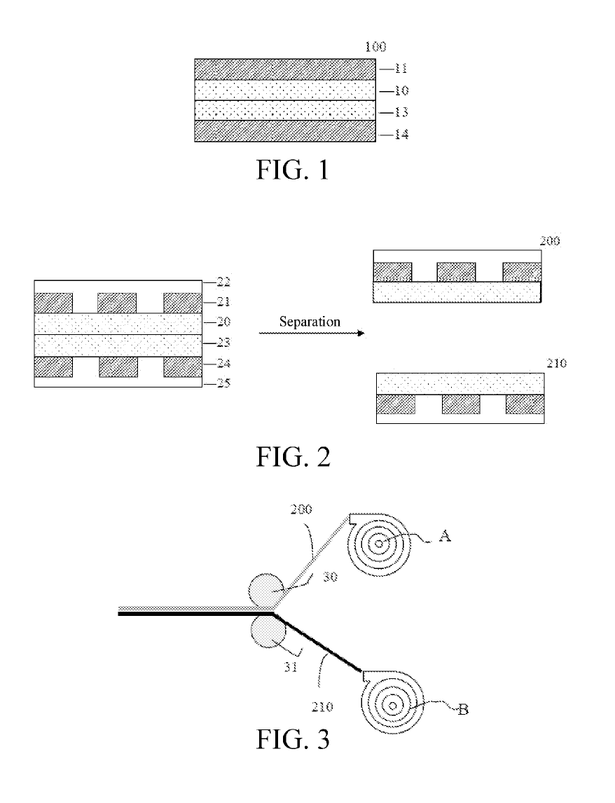

FIG. 1 is a schematic view of a metal clad laminate having a polyimide layer according to the present disclosure. As shown in FIG. 1, the metal clad laminate 100 comprises a first metal foil 11; a first polyimide layer 10 directly disposed on the first metal foil 11; a second metal foil 14; and a second polyimide layer 13 directly disposed on the second metal foil 14. The first polyimide layer and the first metal foil, and the second polyimide layer and the second metal foil have a close or substantially the same coefficient of thermal expansion.

At least one of the first polyimide layer 10 and the second polyimide layer 13 (preferably both) is made of the polyimide precursor composition according to the present disclosure. The polymeric structure in the polyimide layer contains (i) a divalent siloxane organic group having formula (A), (ii) C₂-C₁₄alkylene, or a combination thereof such that it provides adhesion upon hot pressing.

The inventors also found that when at least one of the first polyimide layer and the second polyimide layer has a glass transition temperature ranging from 260 to 340° C., preferably from 270 to 320° C., and more preferably from 280 to 310° C., it is more beneficial to provide excellent adhesion upon hot pressing.

According to one embodiment of the present disclosure, the first polyimide layer and the second polyimide layer are each a polyimide made using the polyimide precursor composition of the present disclosure, and have a glass transition temperature ranging from 260 to 340° C., preferably from 270 to 320° C., and more preferably from 280 to 310° C.

Based on the above research, the present disclosure provides the above-mentioned polyimide precursor composition which results in a polyimide layer having a desired glass transition temperature and provides adhesion upon hot pressing when applied to a metal clad laminate.

According to the present disclosure, the first metal foil and the second metal foil are each a metal or alloy having a coefficient of thermal expansion ranging from about 15 to about 25 ppm/° C., for example, but not limited to: aluminum, copper, silver, an alloy containing any combination of aluminum, copper, and silver, or other alloys having a coefficient of thermal expansion ranging from about 15 to about 25 ppm/° C. According to a preferred embodiment of the present disclosure, the first metal foil and the second metal foil are a copper foil, an aluminum foil or a copper-aluminum alloy foil. The copper foil refers to a foil composed of copper or having copper as the main component (for example, a foil with a copper content of 90 wt % or more), and may be selected from the group consisting of rolled annealed copper foil (Ra copper foil), electrodeposited copper foil (ED copper foil) and a combination thereof. The aluminum foil refers to a foil made of aluminum or having aluminum as the main component (for example, a foil with an aluminum content of 90 wt % or more). The definitions of other metal foils may be deduced by analogy.

The thickness of the first metal foil and the second metal foil is not particularly limited, and generally ranges from about 0.05 to about 50μm, preferably from about 0.1 to about 35μm, and more preferably from about 5 to about 20 μm.

Through using the precursor composition of the present disclosure, the first polyimide layer 10 can be directly disposed on and adhered to the first metal foil 11, and the second polyimide layer 13 can be directly disposed on and adhered to the second metal foil 14, with no need to additionally apply an adhesive or a thermoplastic polyimide (TPI) layer between the metal foil and the polyimide layer to provide an adhesion effect. Accordingly, the process for preparing the metal clad laminate is simplified, and the obtained metal clad laminate has good heat resistance and is applicable to a high-temperature manufacturing process, which is beneficial to the fabrication of semi-conductor components.

In the present disclosure, the thickness of the polyimide layer is not particularly limited, and may be adjusted, depending on the nature of the raw material and the desired property of the product. According to an embodiment of the present disclosure, the thickness of the first polyimide layer and the second polyimide layer may each range from about 1 to about 90 μm, preferably from about 3 to about 50 μm, and more preferably from about 5 to about 30 μm.

In a preferred specific embodiment of the present disclosure, the first polyimide layer and the first metal foil, and the second polyimide layer and the second metal foil have a close or substantially the same coefficient of thermal expansion. Preferably, the first polyimide layer and the second polyimide layer each have a coefficient of thermal expansion ranging from 15 to 25 ppm/° C. The coefficient of thermal expansion of the first polyimide layer and the second polyimide layer may be adjusted, depending on the species of metal foil. The coefficient of thermal expansion of the first polyimide layer and the second polyimide layer may be adjusted to approach the coefficient of thermal expansion of the first metal foil and the second metal foil. For example, when the metal foil is a copper foil, the first polyimide layer and the second polyimide layer preferably each have a coefficient of thermal expansion ranging from 15 to 19 ppm/° C. Because the first polyimide layer and the second polyimide layer have a coefficient of thermal expansion close to that of the first metal foil and that of the second metal foil, warpage is reduced, thus increasing the flatness of the metal clad laminate.

The metal clad laminate of the present disclosure is equivalent to a double-sided flexible metal foil (e.g. copper foil) laminate in structure, is superior to a single-sided flexible copper foil laminate in terms of mechanical properties, and can be used for circuit fabrication simultaneously on both sides. In contrast to the existing double-sided flexible copper foil laminate, in the present disclosure, the peeling strength between the first polyimide layer and the second polyimide layer can be controlled by adjusting the lamination temperature and/or pressure during preparation of the metal clad laminate, to prepare a quasi double-sided two layer metal clad laminate or a double-sided two layer metal clad laminate.

In an specific embodiment of the present disclosure, the peeling strength between the first polyimide layer and the second polyimide layer in the quasi double-sided two layer metal clad laminate ranges from 1 to 500 gf/cm, and preferably from 3 to about 100 gf/cm. More preferably, the peeling strength ranges from 5 to about 50 gf/cm to avoid the tendency for warpage upon separation due to the high adhesion between the first polyimide layer and the second polyimide layer. In this embodiment, the quasi double-sided two layer metal clad laminate can be used for circuit fabrication on both sides of the metal clad laminate, to prepare two separate flexible printed circuit boards. The first polyimide layer and the second polyimide layer have a suitable peeling strength at the interface therebetween, and accordingly may be separated from each other at the interface after the fabrication of the component is complete, to obtain two flexible printed circuit boards at the same time. The flexible printed circuit board prepared with the metal clad laminate of the present disclosure has a structure equivalent to that of the flexible printed circuit board prepared with a single-sided FCCL, is light and thin and has good flexibility. However, compared with the process using single-sided FCCL, two flexible printed circuit boards can be prepared at the same time in a single process by using the quasi double-sided two layer metal clad laminate according to the present disclosure. As such, productivity can be raised and process time can be reduced. In addition, the common single-sided FCCLs tend to warp. Therefore, during printing of a circuit, a photoresist is applied not only to the surface of the copper foil for circuit fabrication, but also to the surface of the polyimide layer, such that structural balance is achieved on two opposite sides of the FCCL, thereby alleviating the occurrence of warpage. The photoresist is removed in a subsequent step. However, this increases the fabrication cost. The quasi double-sided two layer metal clad laminate having the polyimide of the present disclosure has a symmetric structure per se and can be used for circuit fabrication simultaneously on both sides. Therefore, compared with a common single-sided FCCL, the metal clad laminate of the present disclosure is not prone to warp, and can be used in an expeditious and economical manner to fabricate a flexible printed circuit board.

In another specific embodiment of the present disclosure, the peeling strength between the first polyimide layer and the second polyimide layer in the double-sided two layer metal clad laminate is greater than 500 gf/cm, preferably greater than 800 gf/cm, and more preferably greater than 1000 gf/cm. In this embodiment, the peeling strength is substantial and the adhesion is good at the interface between the first polyimide layer and the second polyimide layer. Therefore, the double-sided metal clad laminate is useful in the fabrication of a double-side wired flexible printed circuit board.

The present disclosure further provides a method for preparing the metal clad laminate. The method according to the present disclosure comprises:
(a) providing a first metal film comprising a first metal foil and a first polyimide layer directly disposed on the first metal foil;
(b) providing a second metal film comprising a second metal foil and a second polyimide layer directly disposed on the second metal foil; and
(c) laminating the first polyimide layer of the first metal film to the second polyimide layer of the second metal film,
   wherein the first metal foil and the second metal foil each have a coefficient of thermal expansion ranging from 15 to 25 ppm/° C.

The materials and properties of the first metal foil, the second metal foil, the first polyimide layer and the second polyimide layer are as described herein above.

In steps (a) and (b), the first metal film and the second metal film are each a flexible two-layer metal film without adhesive. The method for preparing the first metal film and the second metal film is not particularly limited, and may be for example sputtering/plating, casting or hot lamination. For example: 1. in the sputtering/plating process, a layer of metal film (approximately below 1 μm) is deposited by sputtering onto a polyimide film prepared by the polyimide precursor composition of the present disclosure in high vacuum environment, the surface is roughened by lithographic etching, and then the metal layer is increased to a desired thickness by electroplating. 2. In the casting process, the polyimide precursor composition of the present disclosure is applied onto a metal foil which is used as a carrier, and then a flexible two-layer laminate is formed after high-temperature cyclization. 3. In the hot lamination process, a polyimide film prepared by the polyimide precursor composition of the present disclosure is used as a carrier, a metal foil is disposed on a thermoplastic polyimide, and the thermoplastic polyimide is melted again and laminated to the metal foil under a nitrogen atmosphere by a heated roller under appropriate lamination pressure, to form a two-layer flexible laminate. The casting process is preferred.

According to an embodiment of the present disclosure, an aromatic diamine monomer and a diaminosiloxane monomer and/or an alkylene diamine monomer may first react with an aromatic dianhydride to prepare a amic acid ester oligomer of formula (I) of the present disclosure (for example, but not limited to, at 0 to 80° C. for 1 to 48 hrs) and to obtain the polyimide precursor composition of the present disclosure after the addition of suitable additives. Then the polyimide precursor composition is applied onto a metal foil (to a thickness of, for example, but not limited thereto, about 2 to 180 μm), pre-heated to remove the solvent (for example, but not limited to, at 50 to 200° C. for 1 to 20 min), and then further heated, to allow the amic acid ester oligomer to dehydrate and cyclize into a polyimide (for example, but not limited to, at 250 to 350° C. for 30 to 180 min).

According to another embodiment of the present disclosure, a glass or plastic may be used as a carrier, and a polyimide precursor or a polyimide precursor composition may be coated onto the carrier, to form a semi-finished product comprising the carrier and a resin layer. The semi-finished product is dried by heating to remove the solvent, thus forming a product comprising the carrier and the resin layer. A metal foil layer is formed on the surface of the resin layer of the product by sputtering/plating or hot lamination as described above, and then a two-layer flexible laminate is prepared by carrying out a further heat treatment after the removal of the glass or plastic carrier. The plastic carrier is preferably polyethylene terephthalate, polymethyl methyacrylate, polycyclic olefins, cellulose triacetate or a mixture thereof.

In step (c), no adhesive exists between the first polyimide layer and the second polyimide layer. Step (c) can be carried out by any method, preferably by a roll-to-roll method in which the first polyimide layer of the first metal film faces the second polyimide layer of the second metal film and then is laminated thereon. In step (c), the lamination may be carried out in any way, for example, but not limited thereto, roller lamination, hot press, vacuum lamination, or vacuum press, and preferably roller lamination. If necessary, a protective film may be applied to and laminated together with the metal film (as protective film/first metal film or second metal film/protective film). The type of protective film is not particularly limited; for example, NPI available from KANEKA Corporation may be used as a protective film.

At least one of the polyimide layers used in the process comprising steps (a)-(c) is prepared by the precursor composition of the present disclosure, has a glass transition temperature ranging from 260 to 340° C., and excellent thermal stability. In addition, it has a coefficient of thermal expansion close to that of the metal foil, thus avoiding warpage. Through using the precursor composition of the present disclosure, adhesion generates after the lamination of the first polyimide layer and the second polyimide layer. For example, the first polyimide layer may be superposed onto the second polyimide layer, and then laminated in a roller press at an elevated temperature under an elevated pressure such that the adhesion strength can be increased. The temperature and pressure described above depend on the desired peeling strength between the first polyimide layer and the second polyimide layer.

The lamination in step (c) is preferably carried out at a temperature greater than the glass transition temperature of the first polyimide layer and the second polyimide layer. The lamination temperature and pressure may be adjusted depending on the product to be produced. It is found by the present inventors through repeated experiments and research that the quasi double-sided two layer metal clad laminate or double-sided two layer metal clad laminate may be prepared by taking into consideration the lamination temperature and pressure in combination with the glass transition temperatures of the first polyimide layer and the second polyimide layer.

According to a specific embodiment of the present disclosure, the glass transition temperature of the first polyimide layer and the second polyimide layer is in the range of 260 to 340° C., the lamination temperature is controlled to 300 to 390° C., and the lamination line pressure is controlled to 1 to 60 kgf/cm. The resulting metal clad laminate is a quasi double-sided two layer metal clad laminate, and the peeling strength at the interface between the first polyimide layer and the second polyimide layer is from 1 to 500 gf/cm. According to a specific embodiment of the present disclosure, the quasi double-sided two layer metal clad laminate may have a peeling strength of 3, 5, 6, 7, 8, 10, 15, 30, 45, 60, 75, 90, 100, 130, 150, 200, 300, 400 or 500 gf/cm. According to a preferred embodiment of the present disclosure, the first polyimide layer and the second polyimide layer are laminated by roller lamination using a roller press at a lamination temperature that is preferably in the range of 310 to 370° C., and under a lamination line pressure that is preferably in the range of 5 to 50 kgf/cm. The resulting metal clad laminate is a quasi double-sided two layer metal clad laminate, and the peeling strength at the interface between the first polyimide layer and the second polyimide layer is preferably from 3 to 100 gf/cm, and more preferably from 5 to 50 gf/cm. For the quasi double-sided two layer metal clad laminate formed under the above lamination conditions, appropriate adhesion exists between the first polyimide layer and the second polyimide layer. Therefore, the quasi double-sided two layer metal clad laminate can be used for fabrication of a flexible circuit board through a relevant process for preparing such. After the flexible circuit board is prepared, two single-sided flexible circuit boards may be easily obtained by separating the first polyimide layer from the second polyimide layer. The above-mentioned line pressure refers to a force for lamination applied by two rollers in a roller heat press machine onto a substrate with a constant width divided by the width of the substrate.

According to another specific embodiment of the present disclosure, the glass transition temperature of the first polyimide layer and the second polyimide layer is in the range of 260 to 340° C. By adjusting the lamination temperature and pressure, a double-sided two layer metal clad laminate can also be prepared in the present disclosure. For example, using a lamination temperature in the range of 350 to 400° C. and a lamination line pressure in the range of 100 to 200 kgf/cm, a peeling strength greater than 500 gf/cm, preferably greater than 800 gf/cm, and more preferably greater than 1000 gf/cm, is produced at the interface between the first polyimide layer and the second polyimide layer, and the first polyimide layer and the second polyimide layer can be effectively adhered together without separation from each other.

To prevent warpage during the process for preparing a single-sided flexible circuit board, a dry film photoresist is generally attached to both an upper and a lower surface of the single-sided copper clad laminate. However, this causes the waste of photoresist. In addition, to save time in processing, persons skilled in the art use an adhesive tape to adhere the polyimide layers of two single-sided copper clad laminates together, and separate them after the fabrication of circuits on both sides. However, attachment by an adhesive tape is generally applicable only to a sheet by sheet process, and encounters difficulty when applied to a roll to roll process, and therefore, it is unable to continuously and rapidly produce the products by the roll to roll process in this case. Moreover, because such adhesive tapes are mostly epoxy resins or acrylates without high temperature resistance and having poor chemical resistance, and the fabrication of printed circuit boards generally involves acidic electroplating, acidic etching and alkaline development, gold plating, electroless nickel immersion gold (ENIG) and other processes, the adhesive tapes generally need to be removed upon failure (for example, after etching) and a new adhesive tape is required for reattachment such that subsequent processes can be carried out. Such fabrication process is complicated and may result in adhesive residue. The method for preparing the metal clad laminate according to the present disclosure has none of the above disadvantages, and is more suitable for use in a roll to roll process. Furthermore, during the preparation of a double-sided flexible circuit board in the prior art, due to the poor adhesion (generally, the peeling strength is about <1 gf/cm) between the polyimide layers, a thermoplastic polyimide is commonly used to provide adhesion to the polyimide layers. For example, ROC (Taiwan) Patent Application No. 200709751A discloses bonding of two polyimide layers with a thermoplastic polyimide, which however increases the complexity of the process. Moreover, in general, the glass transition temperature of a thermoplastic polyimide can be lowered by introducing a flexible group (e.g. C═O, —O—, and —S—) to reduce the rigidity of the backbone, a monomer having an asymmetrically structure to reduce the symmetry of the polymer, or a monomer having a non-planar structure to reduce the co-planar structure of the polymer, or by reducing its regularity. Generally, a thermoplastic polyimide has a lower glass transition temperature (Tg) (about 170 to 250° C.) and higher thermal expansion coefficient (about 40 to 90 ppm/° C.), and is prone to cause warpage of the laminate. Moreover, the low glass transition temperature of the thermoplastic polyimide is adverse to the heat resistance of the double-sided laminate.

Accordingly, after preparing a polyimide layer from the precursor composition of the present disclosure, a quasi double-sided two layer metal clad laminate may be prepared by appropriately adjusting the lamination temperature and pressure, and easily separated into two single-sided flexible circuit boards after the fabrication of flexible printed circuits on both sides of the quasi double-sided two layer metal clad laminate. This eliminates the disadvantage currently existing in the industry that a dry film photoresist is required to be attached to both an upper and a lower surface of a single-sided copper clad laminate or an adhesive tape is used in the preparation of a single-sided flexible circuit board, and thus results in the advantages of a simplified process and reduced cost. Also, after preparing a polyimide layer from the precursor composition of the present disclosure, a double-sided two layer metal clad laminate may be prepared by appropriately adjusting the lamination temperature and pressure so that the disadvantage existing in the industry of use of a thermoplastic polyimide in the preparation of a double-sided metal clad laminate can be eliminated. This lowers production costs while simultaneously enhancing the heat resistance of the laminate.

The metal clad laminate of the present disclosure is useful in the preparation of a single-sided or double-sided flexible circuit board. In the present disclosure, because the metal clad laminate is free of adhesive or has no thermoplastic polyimide layer for adhesion between the metal foil and the polyimide layer, a light and thin flexible circuit board can be fabricated. In addition, warpage is reduced due to the close coefficients of thermal expansion of the polyimide layer and the metal foil.

Therefore, the present disclosure further provides a method for preparing a single-sided flexible circuit board by using the quasi double-sided two layer metal clad laminate, which further comprises the steps of:
(d) forming at least one circuit unit respectively on the surface of the first metal foil and the second metal foil of the metal clad laminate; and
(e) separating the first polyimide layer from the second polyimide layer, to form two single-sided flexible circuit boards.

It should be understood by those of skill in the art that the surface of the first metal foil on which the circuit unit is formed in step (d) refers to a surface of the first metal foil opposing the surface of the first metal foil adhered to the first polyimide layer, and the surface of the second metal foil on which the circuit unit is formed refers to a surface of the second metal foil opposing the surface of the second metal foil adhered to the second polyimide layer.

The method for forming the circuit unit in step (d) is not particularly limited, and may be any suitable method known to those skilled in the art. For example, as shown in FIG. 2 (which is a schematic view showing the preparation of two single-side wired flexible circuit boards by using the metal clad laminate containing the polyimide according to the present disclosure), each of the first metal foil 21 on the first polyimide layer 20 and the second metal foil 24 on the second polyimide layer 23 may be patterned by the steps including exposure, development, etching and photoresist removal, to prepare an individual circuit unit. Then, a coverlay 22 and 25 may be optionally applied to the patterned first metal foil 21 and/or second metal foil 24 to protect the circuit unit, and an ENIG process (not shown in the figure) may also be carried out as desired. Subsequently, in step (e), two single-side wired flexible circuit boards 200 and 210 are formed by separation at the interface between the first polyimide layer 20 and the second polyimide layer 23 (see FIG. 2).

Due to the presence of an appropriate but not overly high peeling strength (ranging from 1 to 500 gf/cm) at the interface between the first polyimide layer and the second polyimide layer, in step (e), two single-sided flexible circuit boards 200 and 210 are debonded by a roll-to-roll process at the interface with the aid of rollers 30 and 31, and wound into rolls A and B of single-sided flexible circuit board (see FIG. 3, a schematic view showing the separation of two single-sided wired flexible circuit boards).

It should be understood by those skilled in the art that due to the presence of metal foils on both sides, the metal clad laminate of the present disclosure is useful not only in the preparation of a single-sided flexible circuit board, but also in the preparation of a double-sided flexible circuit board, especially when the first polyimide layer and the second polyimide layer have a peeling strength that is greater than 500 gf/cm at the interface therebetween.

Therefore, the present disclosure further provides a method for preparing a double-sided flexible circuit board by using the double-sided two layer metal clad laminate, which further comprises the steps of:
(f) forming at least one circuit unit respectively on the surface of the first metal foil and the second metal foil of the metal clad laminate.

The method for forming the circuit unit in step (f) is as described in step (d). The wires formed on the upper and lower sides can electrically connect to each other using any suitable method known to those skilled in the art, for example, but not limited thereto, by etching the exposed first polyimide layer and second polyimide layer after step (d) to form a via hole, sputtering a seed layer in the via hole and then plating a conductive component.

In view of the above, by using the precursor composition of the present disclosure, the present disclosure provides a novel metal clad laminate, which not only has the advantages of a single-sided laminate, i.e., being light and thin, and but also has the advantages of a double-sided laminate, i.e., being useful for circuit fabrication simultaneously on both sides. In addition, the metal clad laminate of the present disclosure is applicable to the preparation of either a single-sided flexible circuit board or a double-sided flexible circuit board, thus having a broader range of applications compared with the existing single-sided FCCLs or double-sided FCCLs. Moreover, the metal clad laminate of the present disclosure to is simple to prepare and low in cost, thus having economic advantages.

Preferred embodiments of the present disclosure are disclosed as above, which, however, are provided for further illustrating instead of limiting the scope of the present disclosure. Any modifications and variations easily made by those of skill in the art are contemplated within the disclosure of the specification and the scope of the appended claims of the present disclosure.

### EXAMPLES

The abbreviations mentioned in examples below are defined as follows:

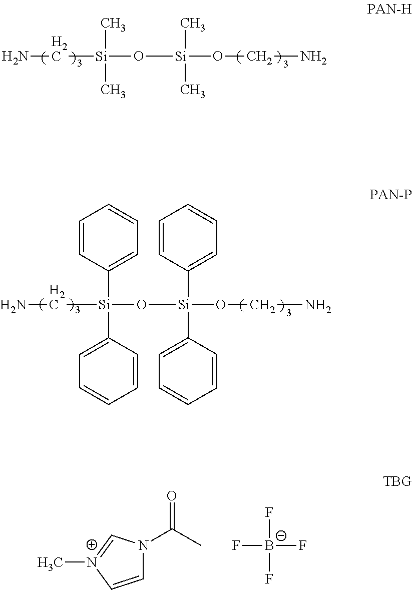

Under nitrogen, imidazole was dissolved in anhydrous THF, and an appropriate amount of acetic anhydride was dropped slowly into the solution; then reaction was carried out for about half an hour accompanied by exothermic phenomena. After the reaction was completed, the solvent was removed by vacuum reduced pressure concentration to generate a solid product. Then, the obtained solid was rinsed with n-hexane and filtered to provide a semi-product as white solid. Next, the semi-product was dissolved in dichloromethane, and

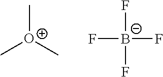

was dropped slowly into the solution at 0° C.; then reaction was carried out for about 2 hours at room temperature. After that, the solution was added to ethyl ether to generate a solid precipitate, and the solution was filtered and the obtained solid was rinsed with ethyl ether again to provide TBG.

DATA: 3,5-diamino-1,2,4-triazole

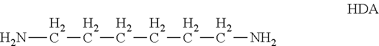

### Preparation Example 1

218.12 g (1 mol) of pyromellitic dianhydride (PMDA) was dissolved in 1291 g of NMP, heated to 50° C. and reacted for 2 hrs with stirring. 11.62 g (0.1 mol) of 2-hydroxyethyl acrylate (HEA) was slowly added dropwise, and reacted for 2 hrs at 50° C. with stirring. Then, 199.24 g (0.995 mol) of 4,4′-oxydianiline (ODA) and 1.24 g (0.005 mol) of PAN-H were added to the solution, and reacted for 6 hrs at 50° C. with stirring after complete dissolution, to obtain a polyimide precursor composition PAA-1 with a solid content of 25% and a viscosity of 8,513 cP. PAN-H accounted for about 0.5 mol % of the total moles of the diamine monomer.

### Preparation Example 2

218.12 g (1 mol) of PMDA was dissolved in 1293 g of NMP, heated to 50° C. and reacted for 2 hrs with stirring. 11.62 g (0.1 mol) of HEA was slowly added dropwise, and reacted for 2 hrs at 50° C. with stirring. Then, 196.24 g (0.98 mol) of ODA and 4.97 g (0.02 mol) of PAN-H were added to the solution, and reacted for 6 hrs at 50° C. with stirring after complete dissolution, to obtain a polyimide precursor composition PAA-2 with a solid content of 25% and a viscosity of 8,037 cP. PAN-H accounted for about 2 mol % of the total moles of the diamine monomer.

### Preparation Example 3

218.12 g (1 mol) of PMDA was dissolved in 1297 g of N-methyl-2-pyrrolidone (NMP), heated to 50° C. and reacted for 2 hrs with stirring.

11.62 g (0.1 mol) of HEA was slowly added dropwise, and reacted for 2 hrs at 50° C. with stirring. Then, 190.43 g (0.951 mol) of ODA and 12.18 g (0.049 mol) of PAN-H were added to the solution, and reacted for 6 hrs at 50° C. with stirring after complete dissolution, to obtain a polyimide precursor composition PAA-3 with a solid content of 25% and a viscosity of 7,084 cP. PAN-H accounted for about 4.9 mol % of the total moles of the diamine monomer.

### Preparation Example 4

218.12 g (1 mol) of PMDA was dissolved in 1300 g of NMP, heated to 50° C. and reacted for 2 hrs with stirring. 11.62 g (0.1 mol) of HEA was slowly added dropwise, and reacted for 2 hrs at 50° C. with stirring. Then, 186.22 g (0.93 mol) of ODA and 17.40 g (0.07 mol) of PAN-H were added to the solution, and reacted for 6 hrs at 50° C. with stirring after complete dissolution, to obtain a polyimide precursor composition PAA-4 with a solid content of 25% and a viscosity of 6,730 cP. PAN-H accounted for about 7 mol % of the total moles of the diamine monomer.

### Preparation Example 5

218.12 g (1 mol) of PMDA was dissolved in 1304 g of NMP, heated to 50° C. and reacted for 2 hrs with stirring. 11.62 g (0.1 mol) of HEA was slowly added dropwise, and reacted for 2 hrs at 50° C. with stirring. Then, 180.22 g (0.9 mol) of ODA and 24.85 g (0.1 mol) of PAN-H were added to the solution, and reacted for 6 hrs at 50° C. with stirring after complete dissolution, to obtain a polyimide precursor composition PAA-5 with a solid content of 25% and a viscosity of 6,073 cP. PAN-H accounted for about 10 mol % of the total moles of the diamine monomer.

### Preparation Example 6

218.12 g (1 mol) of PMDA was dissolved in 1334 g of NMP, heated to 50° C. and reacted for 2 hrs with stirring. 11.62 g (0.1 mol) of 1( )HEA was slowly added dropwise, and reacted for 2 hrs at 50° C. with stirring. Then, 190.43 g (0.951 mol) of ODA and 24.34 g (0.049 mol) of PAN-P were added to the solution, and reacted for 6 hrs at 50° C. with stirring after complete dissolution, to obtain a polyimide precursor composition PAA-6 with a solid content of 25% and a viscosity of 7,122 cP. PAN-P accounted for about 4.9 mol % of the total moles of the diamine monomer.

### Preparation Example 7

218.12 g (1 mol) of PMDA was dissolved in 1290 g of NMP, heated to 50° C. and reacted for 2 hrs with stirring. 11.62 g (0.1 mol) of HEA was slowly added dropwise, and reacted for 2 hrs at 50° C. with stirring. Then, 200.24 g (1 mol) of ODA was added to the solution, and reacted for 6 hrs at 50° C. with stirring after complete dissolution, to obtain a polyimide precursor composition PAA-7 with a solid content of 25% and a viscosity of 8,855 cP. PAN-H accounted for about 0 mol % of the total moles of the diamine monomer.

### Preparation Example 8

218.12 g (1 mol) of PMDA was dissolved in 1307 g of NMP, heated to 50° C. and reacted for 2 hrs with stirring. 11.62 g (0.1 mol) of HEA was slowly added dropwise, and reacted for 2 hrs at 50° C. with stirring. Then, 176.21 g (0.88 mol) of ODA and 29.82 g (0.12 mol) of PAN-H were added to the solution, and reacted for 6 hrs at 50° C. with stirring after complete dissolution, to obtain a polyimide precursor composition PAA-8 with a solid content of 25% and a viscosity of 5,532 cP. PAN-H accounted for about 12 mol % of the total moles of the diamine monomer.

### Preparation Example B1

294.22 g (1 mol) of 3,3′,4,4′-biphenyltetracarboxylic dianhydride (BPDA) was dissolved in 1298 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of p-phenylene diamine (PPDA), 39.05 g (0.195 mol) of ODA, and 1.24 g (0.005 mol) of PAN-H were added to the solution, and reacted for 6 hrs at 50° C. with stirring after complete dissolution, to obtain a polyimide precursor composition PAA-B1 with a solid content of 25% and a viscosity of 8,721 cP. PAN-H accounted for about 0.5 mol % of the total moles of the diamine monomer.

### Preparation Example B2

294.22 g (1 mol) of BPDA was dissolved in 1300 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 36.04 g (0.18 mol) of ODA, and 4.97 g (0.02 mol) of PAN-H were added to the solution, and reacted for 6 hrs at 50° C. with stirring after complete dissolution, to obtain a polyimide precursor composition PAA-B2 with a solid content of 25% and a viscosity of 8,367 cP. PAN-H accounted for about 2 mol % of the total moles of the diamine monomer.

### Preparation Example B3

294.22 g (1 mol) of BPDA was dissolved in 1304 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 30.24 g (0.151 mol) of ODA, and 12.18 g (0.049 mol) of PAN-H were added to the solution, and reacted for 6 hrs at 50° C. with stirring after complete dissolution, to obtain a polyimide precursor composition PAA-B3 with a solid content of 25% and a viscosity of 7,738 cP. PAN-H accounted for about 4.9 mol % of the total moles of the diamine monomer.

### Preparation Example B4

294.22 g (1 mol) of BPDA was dissolved in 1307 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 26.03 g (0.13 mol) of ODA, and 17.40 g (0.07 mol) of PAN-H were added to the solution, and reacted for 6 hrs at 50° C. with stirring after complete dissolution, to obtain a polyimide precursor composition PAA-B4 with a solid content of 25% and a viscosity of 7,194 cP. PAN-H accounted for about 7 mol % of the total moles of the diamine monomer

### Preparation Example B5

294.22 g (1 mol) of BPDA was dissolved in 1312 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 20.02 g (0.1 mol) of ODA, and 24.85 g (0.1 mol) of PAN-H were added to the solution, and reacted for 6 hrs at 50° C. with stirring after complete dissolution, to obtain a polyimide precursor composition PAA-B5 with a solid content of 25% and a viscosity of 6,773 cP. PAN-H accounted for about 10 mol % of the total moles of the diamine monomer.

### Preparation Example B6

294.22 g (1 mol) of BPDA was dissolved in 1341 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 30.24 g (0.151 mol) of ODA, and 24.34 g (0.049 mol) of PAN-P were added to the solution, and reacted for 6 hrs at 50° C. with stirring after complete dissolution, to obtain a polyimide precursor composition PAA-B6 with a solid content of 25% and a viscosity of 7,840 cP. PAN-P accounted for about 4.9 mol % of the total moles of the diamine monomer.

### Preparation Example B7

294.22 g (1 mol) of BPDA was dissolved in 1297 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, and 40.05 g (0.2 mol) of ODA were added to the solution, and reacted for 6 hrs at 50° C. with stirring after complete dissolution, to obtain a polyimide precursor composition PAA-B7 with a solid content of 25% and a viscosity of 9,152 cP. PAN-H accounted for about 0 mol % of the total moles of the diamine monomer.

### Preparation Example B8

294.22 g (1 mol) of BPDA was dissolved in 1315 g of NMP, heated to 50° C. and reacted for 2 hrs with stirring. 11.62 g (0.1 mol) of HEA was slowly added dropwise, and reacted for 2 hrs at 50° C. with stirring. Then, 86.51 g (0.8 mol) of PPDA, 16.02 g (0.08 mol) of ODA, and 29.82 g (0.12 mol) of PAN-H were added to the solution, and reacted for 6 hrs at 50° C. with stirring after complete dissolution, to obtain a polyimide precursor composition PAA-B8 with a solid content of 25% and a viscosity of 6,227 cP. PAN-H accounted for about 12 mol % of the total moles of the diamine monomer.

### Preparation Example C1

4.3 g (0.02 mol) of TGB (cyclization promoter) was added into the polyimide precursor composition PAA-3 prepared in Preparation Example 3 and stirred to obtain a polyimide precursor resin PAA-C1 with a viscosity of 7,145 cP. The weight ratio of the cyclization promoter and the amic acid ester oligomer is about 1:100.

### Preparation Example C2

4.3 g (0.043 mol) of DATA (copper adhesion promoter) was added into the polyimide precursor composition PAA-3 prepared in Preparation Example 3 and stirred to obtain a polyimide precursor resin PAA-C2 with a viscosity of 7,188 cP. The weight ratio of the copper adhesion promoter and the amic acid ester oligomer is about 1:100.

### Preparation Example C3

4.3 g (0.02 mol) of TGB (cyclization promoter) and 4.3 g (0.043 mol) of DATA (copper adhesion promoter) were added into the polyimide precursor composition PAA-3 prepared in Preparation Example 3 and stirred to obtain a polyimide precursor resin PAA-C3 with a viscosity of 7,231 cP. The weight ratio of the cyclization promoter and the amic acid ester oligomer is about 1:100 and the weight ratio of the copper adhesion for and the amic acid ester oligomer is about 1:100.

### Preparation Example D1

218.12 g (1 mol) of PMDA was dissolved in 1297 g of NMP, heated to 50° C. and reacted for 2 hrs with stirring. 11.62 g (0.1 mol) of HEA was slowly added dropwise, and reacted for 2 hrs at 50° C. with stirring. Then, 190.43 g (0.951 mol) of ODA and 2.9 g (0.025 mol) of

HDA were added to the solution, and reacted for 6 hrs at 50° C. with stirring after complete dissolution, to obtain a polyimide precursor resin PAA-D1 with a solid content of 25% and a viscosity of 8,215 cP. HDA accounted for about 2.5 mol % of the total moles of the diamine monomer.

### Preparation Example D2

218.12 g (1 mol) of PMDA was dissolved in 1297 g of NMP, heated to 50° C. and reacted for 2 hrs with stirring. 11.62 g (0.1 mol) of HEA was slowly added dropwise, and reacted for 2 hrs at 50° C. with stirring. Then, 190.43 g (0.951 mol) of ODA and 5.78 g (0.049 mol) of RDA were added to the solution, and reacted for 6 hrs at 50° C. with stirring after complete dissolution, to obtain a polyimide precursor resin PAA-D2 with a solid content of 25% and a viscosity of 7,329 cP. HDA accounted for about 4.9 mol % of the total moles of the diamine monomer.

<Preparation of Metal Clad Laminate>

### Example 1

### Quasi Double-Sided Two Layer Metal Clad Laminate

The polyimide precursor composition PAA-1 synthesized in Preparation Example 1 was evenly roll coated onto a copper foil (VLP copper foil, ⅓ oz (12 μm), provided by Changchun petrochemical company), heated at 120° C. for 5 min, and then heated for 120 min in a nitrogen oven at 350° C., to obtain a single-sided copper clad laminate with a polyimide coating. The polyimide coating is about 12 μm thick.

Two single-sided copper clad laminates fabricated as above were superimposed with the polyimide layers as internal layers and the copper foils as external layers, then laminated by a heated roller under a line pressure of 20 kgf/cm at a lamination temperature of 380° C., and then cooled, to obtain a quasi double-sided two layer metal clad laminate Cu—PI-1 of the present disclosure.

The above-mentioned line pressure refers to a force for lamination applied by two rollers in a roller heat press machine onto a substrate with a constant width divided by the width of the substrate and thus is the line pressure for lamination.

### Example 2

### Double-Sided Two Layer Metal Clad Laminate

The process was the same as that in Example 1, except that the lamination conditions were changed to line pressure of 190 kgf/cm, and lamination temperature of 400° C. A metal clad laminate Cu—PI-2 of the present disclosure was obtained after cooling.

### Example 3

### Quasi Double-Sided Two Layer Metal Clad Laminate

The process was the same as that in Example 1, except that the polyimide precursor composition PAA-2 was used instead, and the lamination conditions were changed to line pressure of 20 kgf/cm, and lamination temperature of 360° C. A metal clad laminate Cu—PI-3 of the present disclosure was obtained after cooling.

### Example 4

### Double-Sided Two Layer Metal Clad Laminate

The process was the same as that in Example 1, except that the polyimide precursor composition PAA-2 was used instead, and the lamination conditions were changed to line pressure of 140 kgf/cm, and lamination temperature of 390° C. A metal clad laminate Cu—PI-4 of the present disclosure was obtained after cooling.

### Example 5

### Quasi Double-Sided Two Layer Metal Clad Laminate

The process was the same as that in Example 1, except that the polyimide precursor composition PAA-3 was used instead, and the lamination conditions were changed to line pressure of 20 kgf/cm, and lamination temperature of 360° C. A metal clad laminate Cu—PI-5 of the present disclosure was obtained after cooling.

### Example 6

### Quasi Double-Sided Two Layer Metal Clad Laminate

The process was the same as that in Example 1, except that the polyimide precursor composition PAA-3 was used instead, and the lamination conditions were changed to line pressure of 60 kgf/cm, and lamination temperature of 320° C. A metal clad laminate Cu—PI-6 of the present disclosure was obtained after cooling.

### Example 7

### Double-Sided Two Layer Metal Clad Laminate

The process was the same as that in Example 1, except that the polyimide precursor composition PAA-3 was used instead, and the lamination conditions were changed to line pressure of 190 kgf/cm, and lamination temperature of 350° C. A metal clad laminate Cu—PI-7 of the present disclosure was obtained after cooling.

### Example 8

### Double-Sided Two Layer Metal Clad Laminate

The process was the same as that in Example 1, except that the polyimide precursor composition PAA-3 was used instead, and the lamination conditions were changed to line pressure of 140 kgf/cm, and lamination temperature of 390° C. A metal clad laminate Cu—PI-8 of the present disclosure was obtained after cooling.

### Example 9

### Quasi Double-Sided Two Layer Metal Clad Laminate

The process was the same as that in Example 1, except that the polyimide precursor composition PAA-4 was used instead, and the lamination conditions were changed to line pressure of 20 kgf/cm, and lamination temperature of 340° C. A metal clad laminate Cu—PI-9 of the present disclosure was obtained after cooling.

### Example 10

### Double-Sided Two Layer Metal Clad Laminate

The process was the same as that in Example 1, except that the polyimide precursor composition PAA-4 was used instead, and the lamination conditions were changed to line pressure of 120 kgf/cm, and lamination temperature of 390° C. A metal clad laminate Cu—PI-10 of the present disclosure was obtained after cooling.

### Example 11

### Quasi Double-Sided Two Layer Metal Clad Laminate

The process was the same as that in Example 1, except that the polyimide precursor composition PAA-5 was used instead, and the lamination conditions were changed to line pressure of 20 kgf/cm, and lamination temperature of 330° C. A metal clad laminate Cu—PI-11 of the present disclosure was obtained after cooling.

### Example 12

### Double-Sided Two Layer Metal Clad Laminate

The process was the same as that in Example 1, except that the polyimide precursor composition PAA-5 was used instead, and the lamination conditions were changed to line pressure of 110 kgf/cm, and lamination temperature of 390° C. A metal clad laminate Cu—PI-12 of the present disclosure was obtained after cooling.

### Example 13

### Quasi Double-Sided Two Layer Metal Clad Laminate

The process was the same as that in Example 1, except that the polyimide precursor composition PAA-6 was used instead, and the lamination conditions were changed to line pressure of 20 kgf/cm, and lamination temperature of 370° C. A metal clad laminate Cu—PI-13 of the present disclosure was obtained after cooling.

### Example 14

### Quasi Double-Sided Two Layer Metal Clad Laminate

The process was the same as that in Example 1, except that the polyimide precursor composition PAA-6 was used instead, and the lamination conditions were changed to line pressure of 60 kgf/cm, and lamination temperature of 320° C. A metal clad laminate Cu—PI-14 of the present disclosure was obtained after cooling.

### Example 15

### Double-Sided Two Layer Metal Clad Laminate

The process was the same as that in Example 1, except that the polyimide precursor composition PAA-6 was used instead, and the lamination conditions were changed to line pressure of 140 kgf/cm, and lamination temperature of 390° C. A metal clad laminate Cu—PI-15 of the present disclosure was obtained after cooling.

### Comparative Example 16

The process was the same as that in Example 1, except that the polyimide precursor composition PAA-7 was used instead, and the lamination conditions were changed to line pressure of 140 kgf/cm, and lamination temperature of 390° C. A metal clad laminate Cu—PI-16 of the present disclosure was obtained after cooling.

### Comparative Example 17

The process was the same as that in Example 1, except that the polyimide precursor composition PAA-8 was used instead, and the lamination conditions were changed to line pressure of 20 kgf/cm, and lamination temperature of 330° C. A metal clad laminate Cu—PI-17 of the present disclosure was obtained after cooling.

### Comparative Example 18

The process was the same as that in Example 1, except that the polyimide precursor composition PAA-8 was used instead, and the lamination conditions were changed to line pressure of 110 kgf/cm, and lamination temperature of 390° C. A metal clad laminate Cu—PI-18 of the present disclosure was obtained after cooling.

### Example B1

### Quasi Double-Sided Two Layer Metal Clad Laminate

The process was the same as that in Example 1, except that the polyimide precursor composition PAA-B1 was used instead, and the lamination conditions were changed to line pressure of 20 kgf/cm, and lamination temperature of 380° C. A metal clad laminate Cu—PI-b1 of the present disclosure was obtained after cooling.

### Example B2

### Double-Sided Two Layer Metal Clad Laminate

The process was the same as that in Example 1, except that the polyimide precursor composition PAA-B1 was used instead, and the lamination conditions were changed to line pressure of 190 kgf/cm, and lamination temperature of 400° C. A metal clad laminate Cu—PI-b2 of the present disclosure was obtained after cooling.

### Example B3

### Quasi Double-Sided Two Layer Metal Clad Laminate

The process was the same as that in Example 1, except that the polyimide precursor composition PAA-B2 was used instead, and the lamination conditions were changed to line pressure of 20 kgf/cm, and lamination temperature of 370° C. A metal clad laminate Cu—PI-b3 of the present disclosure was obtained after cooling.

### Example B4

### Double-Sided Two Layer Metal Clad Laminate

The process was the same as that in Example 1, except that the polyimide precursor composition PAA-B2 was used instead, and the lamination conditions were changed to line pressure of 140 kgf/cm, and lamination temperature of 390° C. A metal clad laminate Cu—PI-b4 of the present disclosure was obtained after cooling.

### Example B5

### Quasi Double-Sided Two Layer Metal Clad Laminate

The process was the same as that in Example 1, except that the polyimide precursor composition PAA-B3 was used instead, and the lamination conditions were changed to line pressure of 20 kgf/cm, and lamination temperature of 370° C. A metal clad laminate Cu—PI-b5 of the present disclosure was obtained after cooling.

### Example B6

### Quasi Double-Sided Two Layer Metal Clad Laminate

The process was the same as that in Example 1, except that the polyimide precursor composition PAA-B3 was used instead, and the lamination conditions were changed to line pressure of 60 kgf/cm, and lamination temperature of 320° C. A metal clad laminate Cu—PI-b6 of the present disclosure was obtained after cooling.

### Example B7

### Double-Sided Two Layer Metal Clad Laminate

The process was the same as that in Example 1, except that the polyimide precursor composition PAA-B3 was used instead, and the lamination conditions were changed to line pressure of 190 kgf/cm, and lamination temperature of 350° C. A metal clad laminate Cu—PI-b7 of the present disclosure was obtained after cooling.

### Example B8

### Double-Sided Two Layer Metal Clad Laminate

The process was the same as that in Example 1, except that the polyimide precursor composition PAA-B3 was used instead, and the lamination conditions were changed to line pressure of 140 kgf/cm, and lamination temperature of 390° C. A metal clad laminate Cu—PI-b8 of the present disclosure was obtained after cooling.

### Example B9

### Quasi Double-Sided Two Layer Metal Clad Laminate

The process was the same as that in Example 1, except that the polyimide precursor composition PAA-B4 was used instead, and the lamination conditions were changed to line pressure of 20 kgf/cm, and lamination temperature of 340° C. A metal clad laminate Cu—PI-b9 of the present disclosure was obtained after cooling.

### Example B10

### Double-Sided Two Layer Metal Clad Laminate

The process was the same as that in Example 1, except that the polyimide precursor composition PAA-B4 was used instead, and the lamination conditions were changed to line pressure of 120 kgf/cm, and lamination temperature of 390° C. A metal clad laminate Cu—PI-b10 of the present disclosure was obtained after cooling.

### Example B11

### Quasi Double-Sided Two Layer Metal Clad Laminate

The process was the same as that in Example 1, except that the polyimide precursor composition PAA-B5 was used instead, and the lamination conditions were changed to line pressure of 20 kgf/cm, and lamination temperature of 330° C. A metal clad laminate Cu—PI-b11 of the present disclosure was obtained after cooling.

### Example B12

### Double-Sided Two Layer Metal Clad Laminate

The process was the same as that in Example 1, except that the polyimide precursor composition PAA-B5 was used instead, and the lamination conditions were changed to line pressure of 110 kgf/cm, and lamination temperature of 390° C. A metal clad laminate Cu—PI-b12 of the present disclosure was obtained after cooling.

### Example B13

### Quasi Double-Sided Two Layer Metal Clad Laminate

The process was the same as that in Example 1, except that the polyimide precursor composition PAA-B6 was used instead, and the lamination conditions were changed to line pressure of 20 kgf/cm, and lamination temperature of 370° C. A metal clad laminate Cu—PI-b13 of the present disclosure was obtained after cooling.

### Example B14

### Quasi Double-Sided Two Layer Metal Clad Laminate

The process was the same as that in Example 1, except that the polyimide precursor composition PAA-B6 was used instead, and the lamination conditions were changed to line pressure of 60 kgf/cm, and lamination temperature of 320° C. A metal clad laminate Cu—PI-b14 of the present disclosure was obtained after cooling.

### Example B15

### Double-Sided Two Layer Metal Clad Laminate

The process was the same as that in Example 1, except that the polyimide precursor composition PAA-B6 was used instead, and the lamination conditions were changed to line pressure of 140 kgf/cm, and lamination temperature of 390° C. A metal clad laminate Cu—PI-b15 of the present disclosure was obtained after cooling.

### Comparative Example B16

The process was the same as that in Example 1, except that the polyimide precursor composition PAA-B7 was used instead, and the lamination conditions were kept unchanged, i.e. line pressure of 140 kgf/cm, and lamination temperature of 390° C. A metal clad laminate Cu—PI-b16 of the present disclosure was obtained after cooling.

### Comparative Example B17

The process was the same as that in Example 1, except that the polyimide precursor composition PAA-B8 was used instead, and the lamination conditions were changed to line pressure of 20 kgf/cm, and lamination temperature of 330° C. A metal clad laminate Cu—PI-b17 of the present disclosure was obtained after cooling.

### Comparative Example B18

The process was the same as that in Example 1, except that the polyimide precursor composition PAA-B8 was used instead, and the lamination conditions were changed to line pressure of 110 kgf/cm, and lamination temperature of 390° C. A metal clad laminate Cu—PI-b18 of the present disclosure was obtained after cooling.

### Example C1

### Quasi Double-Sided Two Layer Metal Clad Laminate

The process was the same as that in Example 1, except that the polyimide precursor composition PAA-C1 was used instead, the baking conditions were changed to: dried at 120° C. for 5 min, and then dried for 120 min in a nitrogen filled drying oven at 300° C., and the lamination conditions were changed to line pressure of 20 kgf/cm, and lamination temperature of 360° C. A metal clad laminate Cu—PI-c1 of the present disclosure was obtained after cooling.

### Example C2

### Quasi Double-Sided Two Layer Metal Clad Laminate

The process was the same as that in Example 1, except that the polyimide precursor composition PAA-C2 was used instead, and the lamination conditions were changed to line pressure of 20 kgf/cm, and lamination temperature of 360° C. A metal clad laminate Cu—PI-c2 of the present disclosure was obtained after cooling.

### Example C3

### Quasi Double-Sided Two Layer Metal Clad Laminate

The process was the same as that in Example 1, except that the polyimide precursor composition PAA-C3 was used instead, the baking conditions were changed to: dried at 120° C. for 5 min, and then dried for 120 min in a nitrogen filled drying oven at 300° C., and the lamination conditions were changed to line pressure of 20 kgf/cm, and lamination temperature of 360° C. A metal clad laminate Cu—PI-c3 of the present disclosure was obtained after cooling.

### Example D1

### Quasi Double-Sided Two Layer Metal Clad Laminate

The process was the same as that in Example 1, except that the polyimide precursor composition PAA-D1 was used instead, and the lamination conditions were changed to line pressure of 20 kgf/cm, and lamination temperature of 360° C. A metal clad laminate Cu—PI-d1 of the present disclosure was obtained after cooling.

### Example D2

### Double-Sided Two Layer Metal Clad Laminate

The process was the same as that in Example 1, except that the polyimide precursor composition PAA-D1 was used instead, and the lamination conditions were changed to line pressure of 140 kgf/cm, and lamination temperature of 390° C. A metal clad laminate Cu—PI-d2 of the present disclosure was obtained after cooling.

### Example D3

### Quasi Double-Sided Two Layer Metal Clad Laminate

The process was the same as that in Example 1, except that the polyimide precursor composition PAA-D2 was used instead, and the lamination conditions were changed to line pressure of 20 kgf/cm, and lamination temperature of 360° C. A metal clad laminate Cu—PI-d3 of the present disclosure was obtained after cooling.

### Example D4

### Double-Sided Two Layer Metal Clad Laminate

The process was the same as that in Example 1, except that the polyimide precursor composition PAA-D2 was used instead, and the lamination conditions were changed to line pressure of 190 kgf/cm, and lamination temperature of 350° C. A metal clad laminate Cu-PI-d4 of the present disclosure was obtained after cooling.

<Test Methods of Metal Clad Laminate>

Measurement of glass transition temperature (Tg) of polyimide layer:

A polyimide layer was removed from a single-sided metal clad laminate, and measured for Tg by using a thermal mechanical analyzer (TMA, TA Q400 from Texas Instruments). The measurement range was from 0 to 500° C., and the temperature ramping rate was 10° C./min.

Measurement of Coefficient of Thermal Expansion (CTE) of Polyimide layer:

A polyimide layer was removed from a single-sided metal clad laminate, and measured for CTE by using a thermal mechanical analyzer (TMA, TA Q400 from Texas Instruments). The measurement range was from 0 to 500° C., and the temperature ramping rate was 10° C./min.

Measurement of Peeling Strength A (Peeling Strength Between two Polyimide Layers):

The laminates obtained in the above examples and comparative examples were cut into test strips of 15 cm×1 cm. The two polyimide layers at an end of the test strip were slightly separated, and clipped respectively in a clamping fixture of a micro-computer aided pulling force tester (HT-9102, Hung Ta Instrument Co., Ltd, maximum load: 100 kg). The peeling strength test was conducted by drawing at a vertical angle of 180 degrees between the two slightly separated polyimide layers with a distance of 1 cm from one to the other clamping fixture.

Measurement of Peeling Strength B (Peeling Strength Between the Polyimide Layer and Copper Foil):

Peeling strength B of the single-sided copper clad laminate obtained in Examples 5, Examples C1 to C3 and Examples D1 to D4 before lamination were measured according to the IPC-TM-650 method.

Measurement of Tensile Strength:

The tensile strength test is to measure the mechanical property of the polyimide film of the single-sided copper clad laminate obtained in the examples and comparative examples before lamination with another single-sided copper clad laminate and after removing the copper foil by using a universal tensile strength tester according to the IPC-TM-650 (2.4.19) method. The test result is acceptable if the tensile strength is higher than 100 Mpa.

Flame Retardance Test:

The flame retardance test was carried out on the polyimide film according to the UL94 standard.

<Test Results>

Relevant test results for the above examples and comparative examples are shown in Tables 1-5:

TABLE 1

| | Example 1 | Example 2 | Example 3 | Example 4 | Example 5 | Example 6 | Example 7 | Example 8 | Example 9 |
|---|---|---|---|---|---|---|---|---|---|
| Precursor | PAA-1 | PAA-1 | PAA-2 | PAA-2 | PAA-3 | PAA-3 | PAA-3 | PAA-3 | PAA-4 |
| composition | | | | | | | | | |
| Lamination | 380° C. | 400° C. | 360° C. | 390° C. | 360° C. | 320° C. | 350° C. | 390° C. | 340° C. |
| condition | 20 kgf/cm | 190 kgf/cm | 20 kgf/cm | 140 kg/cm² | 20 kgf/cm | 60 kgf/cm | 190 kgf/cm | 140 kgf/cm | 20 kgf/cm |
| (° C.; kgf/cm) | | | | | | | | | |
| Tg (° C.) | 312 | 312 | 294 | 294 | 288 | 288 | 288 | 288 | 274 |
| CTE (ppm/° C.) | 17.2 | 17.2 | 17.5 | 17.5 | 18.3 | 18.3 | 18.3 | 18.3 | 18.8 |
| Peeling strength | 3 | 532 | 22 | >1000 | 12 | 21 | >1000 | >1000 | 13 |
| A (gf/cm) | | | | | | | | | |
| Peeling strength | | | | | 0.7 | | | | |
| B (gf/cm) | | | | | | | | | |
| Tensile strength | 164 | 164 | 157 | 157 | 123 | 123 | 123 | 123 | 104 |
| (MPa) | | | | | | | | | |
| Flame retardance | V0 | V0 | V0 | V0 | V0 | V0 | V0 | V0 | V0 |
| test | | | | | | | | | |

TABLE 2

| | | | | | | | Comparative | Comparative | Comparative |
|---|---|---|---|---|---|---|---|---|---|
| | Example 10 | Example 11 | Example 12 | Example 13 | Example 14 | Example 15 | Example 16 | Example 17 | Example 18 |
| Precursor | PAA-4 | PAA-5 | PAA-5 | PAA-6 | PAA-6 | PAA-6 | PAA-7 | PAA-8 | PAA-8 |
| composition | | | | (PAN-P) | (PAN-P) | (PAN-P) | | | |
| Lamination | 390° C. | 330° C. | 390° C. | 370° C. | 320° C. | 390° C. | 390° C. | 330° C. | 390° C. |
| condition | 120 kgf/cm | 20 kgf/cm | 110 kgf/cm | 20 kgf/cm | 60 kgf/cm | 140 kgf/cm | 140 kgf/cm | 20 kgf/cm | 110 kgf/cm |
| (° C.; kgf/cm) | | | | | | | | | |
| Tg (° C.) | 274 | 264 | 264 | 293 | 293 | 293 | 325 | 245 | 245 |
| CTE (ppm/° C.) | 18.8 | 19.2 | 19.2 | 17.9 | 17.9 | 17.9 | 17.1 | 20.1 | 20.1 |
| Peeling strength | >1000 | 12 | >1000 | 9 | 16 | >1000 | 0 | 84 | >1000 |
| A (gf/cm) | | | | | | | | | |
| Tensile strength | 104 | 93 | 93 | 121 | 121 | 121 | 178 | 81 | 81 |
| (MPa) | | | | | | | | | |
| Flame retardance | V0 | V0 | V0 | V0 | V0 | V0 | V0 | V1 | V1 |
| test | | | | | | | | | |

TABLE 3

| | Example B1 | Example B2 | Example B3 | Example B4 | Example B5 | Example B6 | Example B7 | Example B8 | Example B9 |
|---|---|---|---|---|---|---|---|---|---|
| Precursor | PAA-B1 | PAA-B1 | PAA-B2 | PAA-B2 | PAA-B3 | PAA-B3 | PAA-B3 | PAA-B3 | PAA-B4 |
| composition | | | | | | | | | |
| Lamination | 380° C. | 400° C. | 370° C. | 390° C. | 370° C. | 320° C. | 350° C. | 390° C. | 340° C. |
| condition | 20 kgf/cm | 190 kgf/cm | 20 kgf/cm | 140 kg/cm² | 20 kgf/cm | 60 kgf/cm | 190 kgf/cm | 140 kgf/cm | 20 kgf/cm |
| (° C.; kgf/cm) | | | | | | | | | |
| Tg (° C.) | 317 | 317 | 298 | 298 | 292 | 292 | 292 | 292 | 281 |
| CTE (ppm/° C.) | 17.3 | 17.3 | 17.7 | 17.7 | 18.4 | 18.4 | 18.4 | 18.4 | 18.9 |
| Peeling strength | 3 | 534 | 16 | >1000 | 8 | 31 | >1000 | >1000 | 11 |
| A (gf/cm) | | | | | | | | | |
| Tensile strength | 198 | 198 | 178 | 178 | 149 | 149 | 149 | 149 | 112 |
| (MPa) | | | | | | | | | |
| Flame retardance | V0 | V0 | V0 | V0 | V0 | V0 | V0 | V0 | V0 |
| test | | | | | | | | | |

TABLE 4

| | | | | | | | Comparative | Comparative | Comparative |
|---|---|---|---|---|---|---|---|---|---|
| | Example | Example | | | Example | | Example | Example | Example |
| | B10 | B11 | Example B12 | Example B13 | B14 | Example B15 | B16 | B17 | B18 |
| Precursor | PAA-B4 | PAA-B5 | PAA-B5 | PAA-B6 | PAA-B6 | PAA-B6 | PAA-B7 | PAA-B8 | PAA-B8 |
| composition | | | | (PAN-P) | (PAN-P) | (PAN-P) | | | |
| Lamination | 390° C. | 330° C. | 390° C. | 370° C. | 320° C. | 390° C. | 390° C. | 330° C. | 390° C. |
| condition | 120 kgf/cm | 20 kgf/cm | 110 kgf/cm | 20 kgf/cm | 60 kgf/cm | 140 kgf/cm | 140 kgf/cm | 20 kgf/cm | 110 kgf/cm |
| (° C.; kgf/cm) | | | | | | | | | |
| Tg (° C.) | 281 | 272 | 272 | 298 | 298 | 298 | 337 | 251 | 251 |
| CTE (ppm/° C.) | 18.9 | 19.4 | 19.4 | 17.6 | 17.6 | 17.6 | 16.7 | 19.9 | 19.9 |
| Peeling strength | >1000 | 10 | >1000 | 7 | 13 | >1000 | 0 | 121 | >1000 |
| A (gf/cm) | | | | | | | | | |
| Tensile strength | 112 | 102 | 102 | 146 | 146 | 146 | 205 | 89 | 89 |
| (MPa) | | | | | | | | | |
| Flame retardance | V0 | V0 | V0 | V0 | V0 | V0 | V0 | V1 | V1 |
| test | | | | | | | | | |

TABLE 5

| | Example C1 | Example C2 | Example C3 | Example D1 | Example D2 | Example D3 | Example D4 |
|---|---|---|---|---|---|---|---|
| Precursor | PAA-C1 | PAA-C2 | PAA-C3 | PAA-D1 | PAA-D2 | PAA-D3 | PAA-D4 |
| composition | | | | | | | |
| Lamination | 360° C. | 360° C. | 360° C. | 360° C. | 390° C. | 360° C. | 350° C. |
| condition | 20 kgf/cm | 20 kgf/cm | 20 kgf/cm | 20 kgf/cm | 140 kgf/cm | 20 kgf/cm | 190 kgf/cm |
| (° C.; kgf/cm) | | | | | | | |
| Tg (° C.) | 288 | 288 | 288 | 295 | 295 | 290 | 290 |
| CTE (ppm/° C.) | 19.3 | 18.3 | 19.3 | 17.7 | 17.7 | 18.5 | 18.5 |
| Peeling strength | 12 | 13 | 12 | 21 | >1000 | 29 | >1000 |
| A (gf/cm) | | | | | | | |
| Peeling strength | 0.8 | 1.3 | 1.4 | 1.2 | 1.2 | 1.3 | 1.3 |
| B (gf/cm) | | | | | | | |
| Tensile strength | 131 | 132 | 136 | 144 | 144 | 115 | 115 |
| (MPa) | | | | | | | |
| Flame retardance | V0 | V0 | V0 | V0 | V0 | V0 | V0 |
| test | | | | | | | |

The test results for Examples 1 to 15 and B1 to B15 show that a quasi double-sided two layer metal clad laminate with an appropriate peeling strength or a double-sided two layer metal clad laminate with a high peeling strength can be prepared by adjusting the lamination temperature and pressure. The results also show that the metal clad laminates obtained in Examples 1 to 15 and B1 to B15 have a coefficient of thermal expansion close to that of the copper foil, and exhibit satisfactory anti-warpage performance and tensile strength.

The addition of a diaminosiloxane monomer can reduce the glass transition temperature of the polyimide layer, as shown by the glass transition temperature of the polyimide layer obtained in Comparative Examples 16 and B16 (without diaminosiloxane monomer) and other examples and comparative examples (with 0.5 mol %, 2 mol %, 4.9 mol %, 7 mol %, 10 mol % and 12 mol % of diaminosiloxane monomer (based on the total moles of the diamine monomer) respectively).

The test results for Comparative Examples 17 and 18 and Comparative Examples B17 and B18 show that where 12 mol % of a diaminosiloxane monomer is used, the glass transition temperature is reduced to 245-251° C., the tensile strength is poor, and the flame retardance is poor as shown by failure to pass the UL94 V0 flammability test.

The test results for Comparative Examples 16 and B16 show that when the divalent organic group does not comprise a divalent siloxane organic group having formula (A), the two polyimide layers cannot be effectively adhered together.

A cyclization promoter was added in Examples C1 and C3 and lowered the temperature for curing the polyimide precursor composition. In view of the results, the curing temperature for C1 and C3 is 300° C. and the cured polyimide still has excellent physical properties (tensile strength).

A copper adhesion promoter was added in Examples C2 and C3. As compared to Example 5 (without copper adhesion promoter), the peeling strength between the polyimide of Examples C2 and C3 and copper foil is greater, which shows that the addition of copper adhesion promoter can increase the adhesion between polyimide and copper foil.

Examples D1 to D4 used an alkylene diamine monomer. The results show that a double-sided two layer metal clad laminate with a high peeling strength or a quasi double-sided two layer metal clad laminate with an appropriate peeling strength can be prepared by adjusting the lamination temperature and pressure. The resulting polyimide have a coefficient of thermal expansion close to that of the copper foil, and its anti-warpage performance and tensile strength can meet the requirements.

Finally, it should be noted that the above embodiments are intended to illustrate instead of limit the technical solution of the present disclosure. Although the present disclosure is described in detail by way of examples, it should be understood by those of ordinary skill in the art that modifications may be made to the technical solutions described in the embodiments, and equivalents may be substituted for some or all the technical features, without essentially departing from the scope of the technical solution described in the embodiments of the present disclosure.

What is claimed is:

1. A polyimide precursor composition, comprising an amic acid ester oligomer of formula (I): 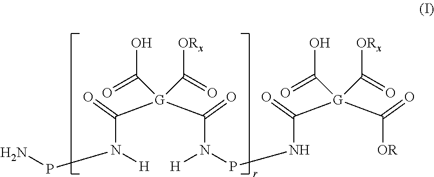
wherein:
r is an integer ranging from 1 to 200;
Each Rₓ is independently H, C₁-C₁₄alkyl or a moiety bearing an ethylenically unsaturated group;
Each R is independently C₁-C₁₄alkyl, C₆-C₁₄aryl or aralkyl, or a moiety bearing an ethylenically unsaturated group;
Each G is independently a tetravalent organic group; and
Each P is independently a divalent organic group, wherein based on the total moles of the divalent organic groups P in the composition, 0.1 mol % to 10 mol % of the divalent organic groups is (i) a divalent siloxane organic group having formula (A), (ii) C₂-C₁₄alkylene, or a combination thereof: 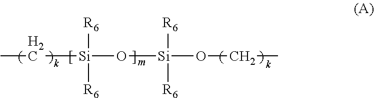
wherein each R₆ is independently H, C₁-C₄alkyl, or phenyl; k may be the same or different and is an integer greater than 0; and m is an integer greater than 0.

2. The polyimide precursor composition according to claim 1, wherein r is an integer ranging from 5 to 150.

3. The polyimide precursor composition according to claim 1, wherein k is an integer ranging from 2 to 5.

4. The polyimide precursor composition according to claim 1, wherein m is an integer ranging from 1 to 5.

5. The polyimide precursor composition according to claim 1, wherein based on the total moles of the divalent organic groups P in the composition, the amount of (i), (ii), or a combination thereof is from 0.5 mol % to 7.5 mol %.

6. The polyimide precursor composition according to claim 5, wherein based on the total moles of the divalent organic groups P in the composition, the amount of (i), (ii), or a combination thereof is from 1 mol % to 5 mol %

7. The polyimide precursor composition according to claim 1, wherein (i) the group having formula (A) is selected from the group consisting of the following radicals or any combination thereof: 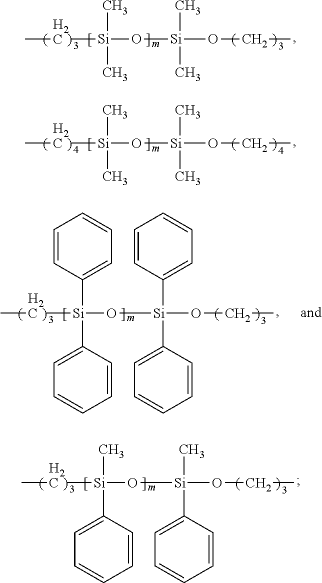
wherein m is an integer ranging from 1 to 5.

8. The polyimide precursor composition according to claim 7, wherein (i) the group having formula (A) is:

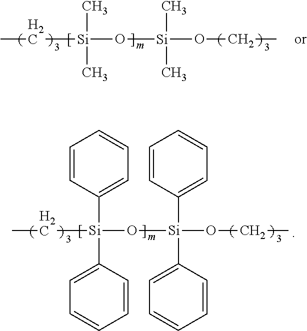

9. The polyimide precursor composition according to claim 1, wherein (ii) is selected from the group consisting of the following radicals or any combination thereof:

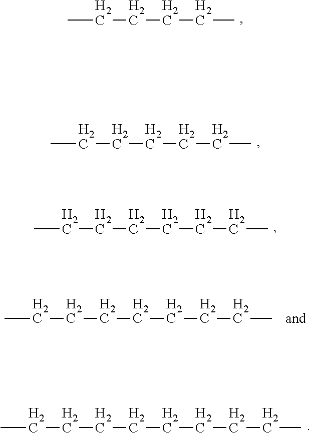

10. The polyimide precursor composition according to claim 1, wherein the divalent organic group P is not crosslinkable.

11. The polyimide precursor composition according to claim 1, wherein the divalent organic groups P further comprises a divalent aromatic group or a divalent heterocyclic group.

12. The polyimide precursor composition according to claim 11, wherein the divalent aromatic group or divalent heterocyclic group is selected from the group consisting of the following radicals or any combination thereof: 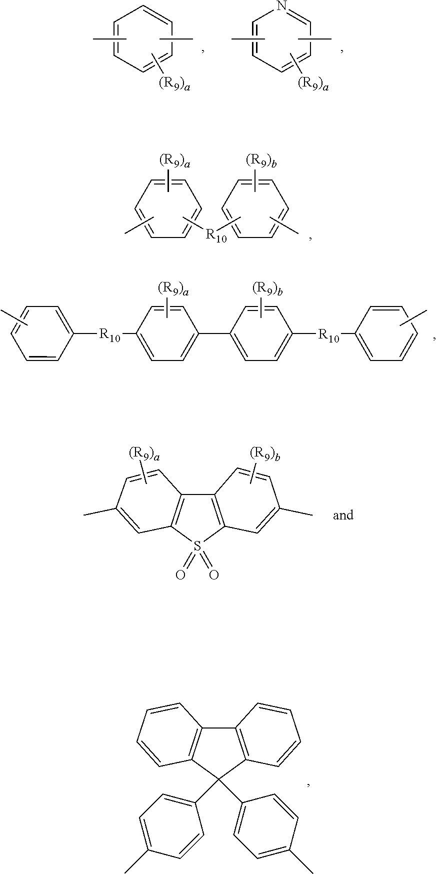
wherein:
each R₉ is independently H, C₁-C₄alkyl, C₁-C₄perfluoroalkyl, C₁-C₄alkoxyl or halogen;
each a is independently an integer from 0 to 4;
each b is independently an integer from 0 to 4;
R₁₀ is a covalent bond or selected from the following groups: 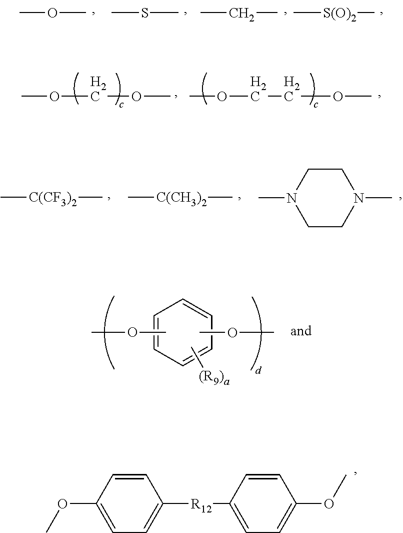
wherein c and d are each independently an integer from 1 to 20, R₁₂ is —S(O)₂—, a covalent bond, C₁-C₄alkylene or C₁-C₄perfluoroalkylene.

13. The polyimide precursor composition according to claim 11, wherein the divalent aromatic group or divalent heterocyclic group is selected from the group consisting of the following radicals or any combination thereof: 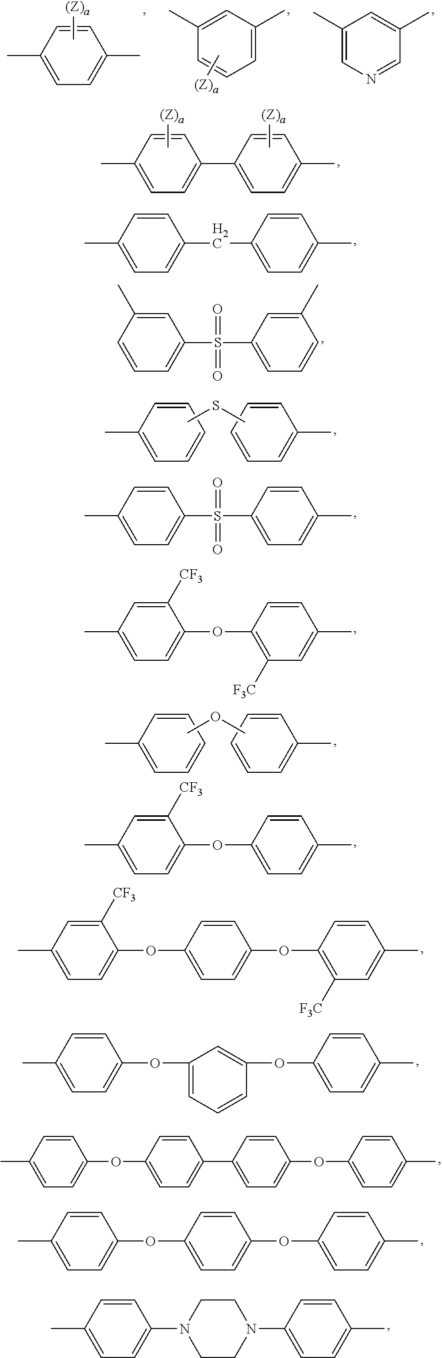 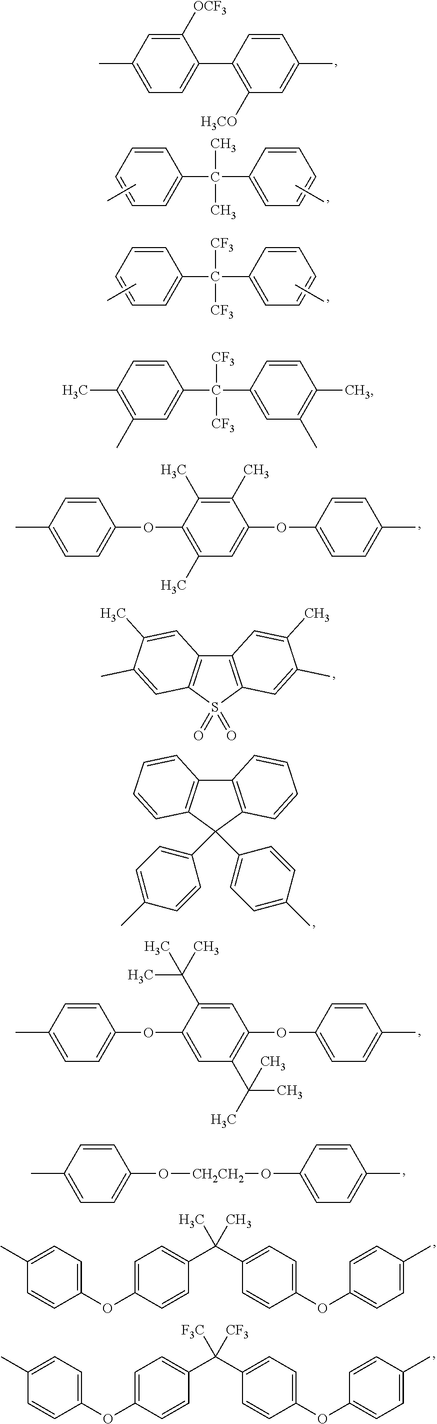 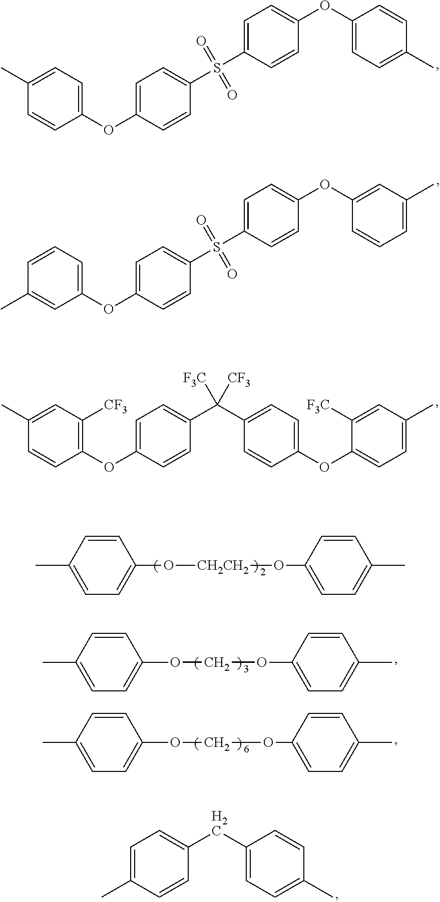
wherein:
each a is independently an integer from 0 to 4; and
each z is independently H, methyl, trifluoromethyl or halogen.

14. The polyimide precursor composition according to claim 11, wherein the divalent aromatic group or divalent heterocyclic group is selected from the group consisting of the following radicals or any combination thereof:

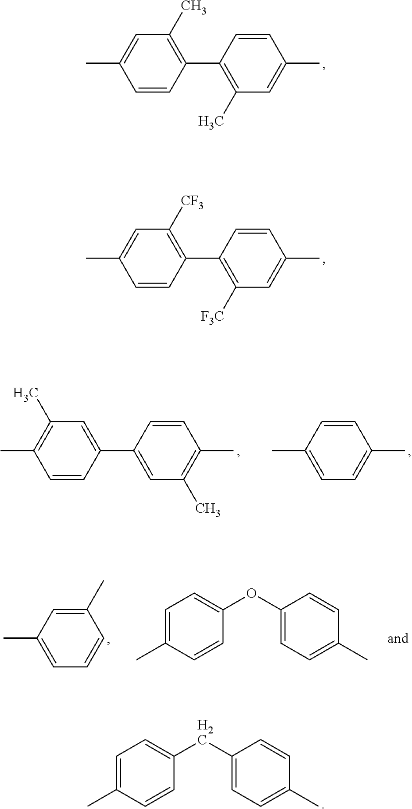

15. The polyimide precursor composition according to claim 1, wherein G is tetravalent aromatic group.

16. The polyimide precursor composition according to claim 15,
wherein G is selected from the group consisting of the following radicals or any combination thereof: 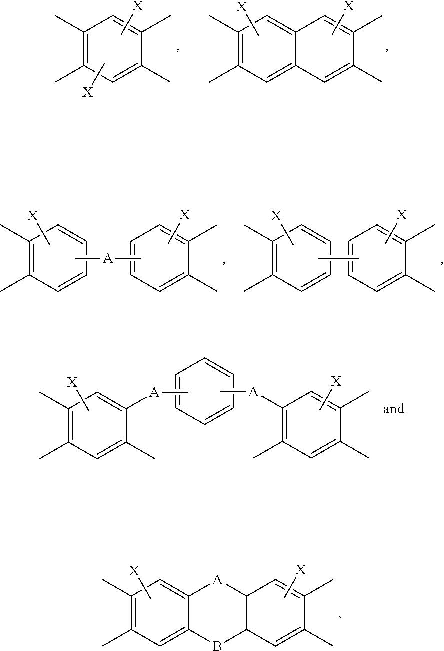
wherein:
each X is independently H, halogen, C₁-C₄perfluoroalkyl, C₁-C₄alkyl;
A and B are independently, at each occurrence, a covalent bond, C₁-C₄alkylene unsubstituted or substituted with one or more radicals selected from C₁-C₄alkyl, C₁-C₄perfluoroalkylene, C₁-C₄alkoxylene, silylene, —O—, —S—, —C(O)—, —OC(O)—, —S(O)₂—, —C(=O)O—(C₁-C₄alkylene)—OC(═O)—, phenylene, biphenylene or 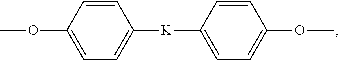
wherein K is —O—, —S(O)₂—, C₁-C₄alkylene or C₁-C₄ perfluoroalkylene.

17. The polyimide precursor composition according to claim 15, wherein G is selected from the group consisting of the following radicals or any combination thereof: 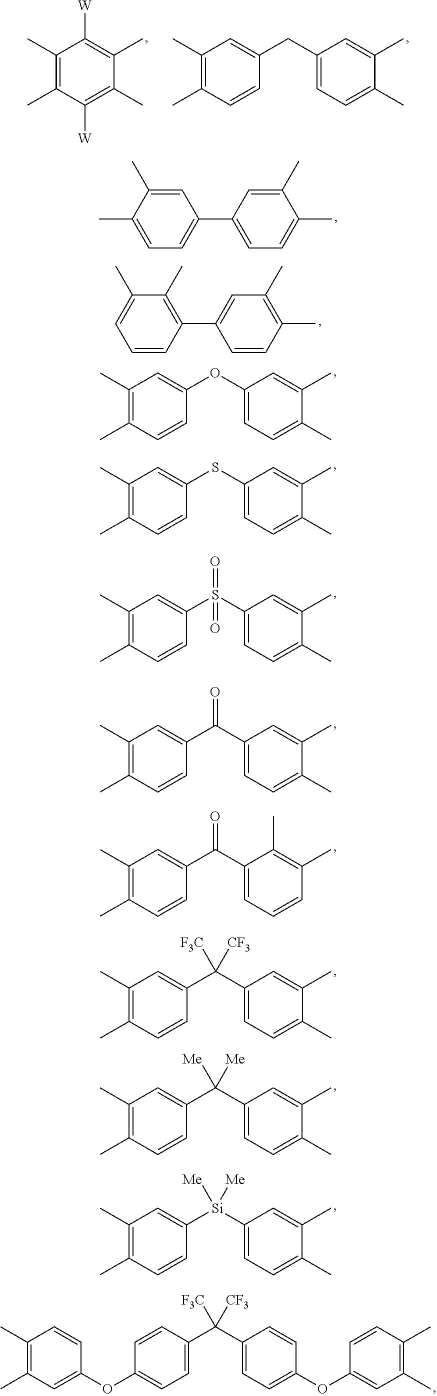 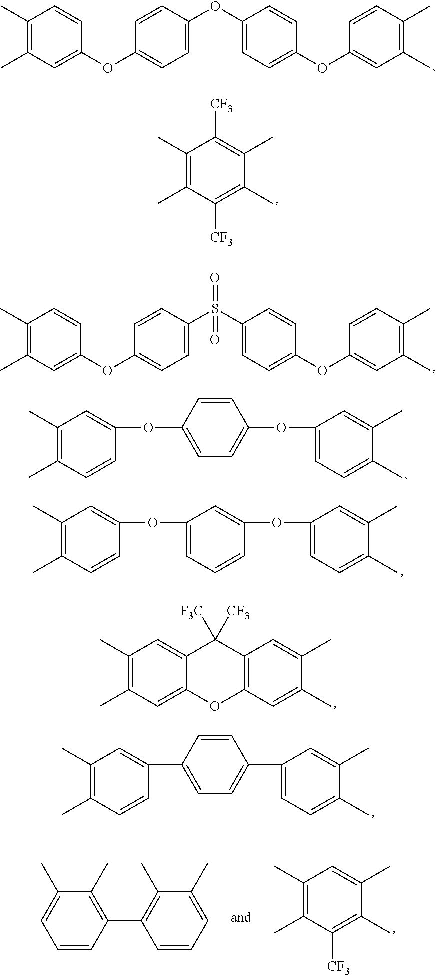
wherein each W is independently H, methyl, trifluoromethyl or halogen.

18. The polyimide precursor composition according to claim 1, wherein each R is independently is selected from the group consisting of the following radicals or any combination thereof:

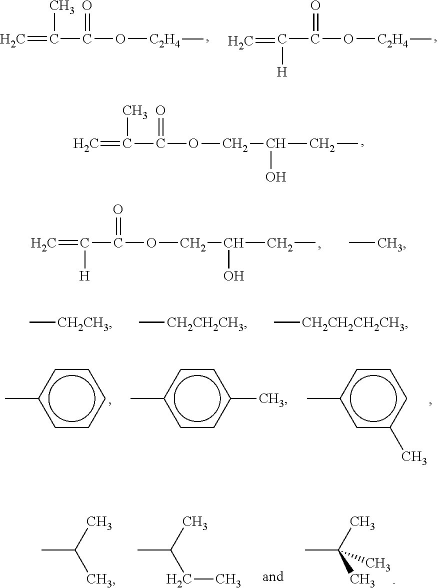

19. The polyimide precursor composition according to claim 1, further comprising an adhesion promoter.

20. The polyimide precursor composition according to claim 19, wherein the adhesion promoter is an imidazole, an pyridine or an triazole; or a fused ring compound containing any of the above-mentioned N-containing heterocycle in its structure.

21. The polyimide precursor composition according to claim 1, further comprising a cyclization promoter having the following formula: 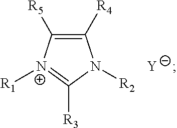
wherein:
R₁ and R₂ are the same or different and are each independently H, C₁-C₆alkyl, C₁-C₆haloalkyl, or C₁-C₆alkyl substituted with one or more C₆-C₁₄aryl, 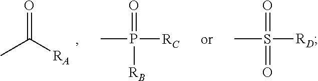
R_{A} is C₁-C₆alkyl, C₁-C₆haloalkyl, C₁-C₈alkoxy unsubstituted or substituted with one or more C₆-C₁₄aryl, or —NR_{E}R_{F}, R_{B}, R_{C}, R_{D}, R_{E} and R_{F} are the same or different, and are each independently H, C₁-C₁₄alkyl unsubstituted or substituted with one or more C₆-C₁₄aryl, or C₆-C₁₄ aryl;
R₃, R₄ and R₅ are the same or different, and are each independently H, straight or branched C₁-C₆alkyl unsubstituted or substituted with one or more C₆-C₁₄aryl, straight or branched C₁-C₆hydroxyalkyl, straight or branched C₁-C₆cyanoalkyl, or C₆-C₁₄aryl; and
Y⊖ is an anionic group.

22. The polyimide precursor composition according to claim 1, wherein the amic acid ester oligomer is in an amount of 10 wt % to 70 wt %, based on the total weight of the polyimide precursor composition.

23. The polyimide precursor composition according to claim 19, wherein the adhesion promoter is in an amount of 0.1 parts by weight to 2 parts by weight, based on 100 parts by weight of the amic acid ester oligomer of formula (I).

24. The polyimide precursor composition according to claim 21, wherein the cyclization promoter is in an amount of 0.1 parts by weight to 2 parts by weight, based on 100 parts by weight of the amic acid ester oligomer of formula (I).

25. The polyimide precursor composition according to claim 1, further comprising a solvent selected from the group consisting of:
dimethyl sulfoxide, diethyl sulfoxide, N,N-dimethyl-methanamide, N,N-diethyl-methanamide, N,N-dimethylacetamide, N,N-diethylacetamide, N-methyl-2-pyrrolidone, N-ethyl-2-pyrrolidone, phenol, o-cresol, m-cresol, p-cresol, xylenol, halogenated phenol, pyrocatechol, tetrahydrofuran, dioxane, dioxolane, propylene glycol monomethyl ether, tetraethylene glycol dimethyl ether, methanol, ethanol, butanol, 2-butoxyethanol, γ-butyrolactone, xylene, toluene, hexamethylphosphoramide, propylene glycol monomethyl ether acetate and a mixture thereof.

26. A polyimide prepared from the precursor composition according to claim 1.

27. A method comprising use of the polyimide precursor composition according to claim 1 for forming a polyimide layer in a metal clad laminate.
